(19) United States
(12) Patent Application Publication
(10) Pub. No.: US 2026/0362804 A1
(43) Pub. Date: Nov. 12, 2026

(54) SEMICONDUCTOR STRUCTURE AND METHOD OF MANUFACTURING THE SAME

(71) Applicant: Taiwan Semiconductor Manufacturing Company, Ltd., Hsinchu (TW)

(72) Inventors: An-Hung Tai, Hsinchu County (TW); Chih-Wei Lee, New Taipei City (TW); Shan-Mei Liao, Hsinchu (TW); Chih-Yu Hsu, Hsinchu County (TW); Kuo-Feng Yu, Hsinchu County (TW)

(21) Appl. No.: 19/364,570

(22) Filed: Oct. 21, 2025

Related U.S. Application Data
(60) Provisional application No. 63/804,258, filed on May 12, 2025.

(51) Int. Cl. H10D 84/85; H10D 30/00; H10D 30/01; H10D 30/43; H10D 62/10; H10D 62/13; H10D 64/66; H10D 64/68; H10D 84/01

(52) U.S. Cl. CPC H10D 84/856; H10D 30/014; H10D 30/0191; H10D 30/43; H10D 30/502; H10D 62/121; H10D 62/151; H10D 64/669; H10D 64/685; H10D 64/691; H10D 84/0144; H10D 84/0177; H10D 84/851

(57) ABSTRACT

A method includes providing a first plurality of stacked channel layers in a first substrate region and a second plurality of stacked channel layers in a second substrate region. A gate dielectric layer is formed wrapping around a channel layer of respective ones of the first plurality of stacked channel layers and the second plurality of stacked channel layers. A nitridation anneal is performed, where the nitridation anneal causes nitrogen to be incorporated into the gate dielectric layer. After performing the nitridation anneal, a first PWFM layer is formed over the gate dielectric layer in the second substrate region. A second PWFM layer is formed over the gate dielectric layer in the first substrate region and over the first PWFM layer in the second substrate region. An NWFM layer is formed over the second PWFM layer in the first and second substrate regions.

### CROSS-REFERENCE TO RELATED APPLICATION

This application claims the benefit of U.S. Provisional Application No. 63/804,258, filed May 12, 2025, the entirety of which is incorporated by reference herein.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA transistors get their name from the gate structure which extends completely around the channel, providing better electrostatic control than FinFETs. FinFETs and GAA transistors are compatible with conventional complementary metal-oxide-semiconductor (CMOS) processes and their three-dimensional structure allows them to be aggressively scaled while maintaining gate control and mitigating SCEs.

In general, GAA transistors may be implemented, for example, in cases where FinFETs can no longer meet performance requirements. However, ever-increasing performance requirements have introduced new challenges to the semiconductor manufacturing process. Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 provides a simplified top-down layout view of a multi-gate device, in accordance with some embodiments;

FIG. 2 is a flow chart of a method of fabricating a semiconductor device 300 according to one or more aspects of the present disclosure;

FIGS. 3, 4, 5, 8, 9, 10, 11, 12, 13, 14, 15, 16A, and 16B provide cross-sectional views of an embodiment of the semiconductor device 300 along a plane substantially parallel to a plane defined by section B-B’ of FIG. 1, in accordance with some embodiments;

FIGS. 6, 7, 17A, and 17B provide cross-sectional views of an embodiment of the semiconductor device 300 along a plane substantially parallel to a plane defined by section A-A’ of FIG. 1, in accordance with some embodiments;

FIG. 18 is a flow chart of a method of fabricating a semiconductor device 1900 according to one or more aspects of the present disclosure; and

FIGS. 19, 20, 21, 22, 23, 24, 25A, and 25B provide cross-sectional views of an embodiment of the semiconductor device 1900 along a plane substantially parallel to a plane defined by section A-A’ of FIG. 1, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Additionally, in the discussion that follows, dimensions (e.g., such as thickness, width, length, etc.) for a given layer or other feature may at times be described using terms such as “substantially equal”, “equal”, or “about”, where such terms are understood to mean within +/- 10% of the recited value or between compared values. For instance, if dimension A is described as being “substantially equal” to dimension B, it will be understood that dimension A is within +/- 10% of dimension B. As another example, if a layer is described as having a thickness of about 100 nm, it will be understood that the thickness of the layer may in a range between 90-110 nm. To be sure, in some embodiments, the terms such as “substantially equal”, “equal”, or “about” may alternatively be understood to mean within a different percentage or range of the recited value, not limited to +/- 10%, where such a different percentage or range may be known by those skilled in the art and may be dependent on various process, material, and/or device conditions or features.

It is also noted that the present disclosure presents embodiments in the form of multi-gate transistors. Multi-gate transistors include those transistors whose gate structures are formed on at least two-sides of a channel region. These multi-gate devices may include a P-type device or an N-type device. Specific examples may be presented and referred to herein as FinFETs, on account of their fin-like structure. FinFET devices may include fins extending from a substrate (or nanostructures extending from a substrate), where the fins are composed of a substantially uniform composition. Also presented herein are embodiments of a type of multi-gate transistor referred to as a gate-all-around (GAA) transistor. A GAA transistor includes any device that has its gate structure, or portion thereof, formed on 4-sides of a channel region (e.g., surrounding a portion of a channel region). Devices presented herein also include embodiments that have channel regions disposed in various nanostructures such as nanosheet channel(s), nanowire channel(s), bar-shaped channel(s), and/or other suitable channel configurations. Presented herein are embodiments of devices that may have one or more nanostructured channel regions (e.g., nanosheets/nanowires) associated with a single, contiguous gate structure. GAA devices may include a plurality of stacked channel layers (e.g., a plurality of stacked nanosheets) that form the channels of a GAA transistor. One of ordinary skill would recognize that the teachings disclosed herein can apply to a single channel (e.g., single nanosheet/nanowire) or any number of channels. One of ordinary skill may recognize other examples of semiconductor devices that may benefit from aspects of the present disclosure. For example, in some cases, aspects of the present disclosure may be equally applicable to planar transistor devices, forksheet devices, complementary FET (CFET) devices, and the like. CFET devices include a first transistor of a first conductivity type (e.g., N-type or P-type) vertically stacked over a second transistor having an opposite conductivity type. In some examples, GAA transistors may be used to implement CFET devices. One of ordinary skill may recognize other embodiments of semiconductor devices that may benefit from aspects of the present disclosure.

Multi-gate devices, such as GAA devices, have been used in a variety of applications, including as a key component of central processing unit (CPU) and graphics processing unit (GPU) design. As merely one example, GAA devices may be used to implement ring oscillators (ROs) in CPUs and GPUs. In prior semiconductor fabrication processing, a post-capping anneal (PCA) process was often used as a crucial step for increasing RO speed and reducing time-dependent dielectric breakdown (TDDB). As semiconductor processes and technology progressed, incorporation of a silicon germanium (SiGe) channel (e.g., in FinFETs) effectively eliminated the need for the PCA process. However, with the ongoing advances in semiconductor technologies and for fabrication of highly-scaled semiconductor devices, there is no industrial-level SiGe GAA channel available and silicon (Si) GAA channels are being used. As a result, the use of the PCA process is once again being considered. However, when the PCA process is applied to such highly-scaled GAA devices, sheet-to-sheet residue (e.g., such as TiN and/or SiOx residue) may remain after a layer removal process, which can decrease RO speed due to increased gate resistance, especially for devices with large sheet widths. In addition, using the PCA process to fabricate highly-scaled GAA devices may cause sheet damage (channel layer damage), which may induce breakdown voltage initial fail, especially in devices with large channel lengths. Thus, existing techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods, and structures thereof, for skipping a PCA process for highly-scaled GAA devices, thereby preventing defects and reducing costs while maintaining or improving device performance and reliability. More generally, embodiments of the present disclosure include: (i) skipping the PCA process, (ii) addition of a nitridation anneal, (iii) addition of a thin P-type work function metal (PWFM) layer right before deposition of an N-type work function metal (NWFM) layer, and (iv) fine tuning middle-end-of-line (MEOL) thermal processing (e.g., which may serve as a source/drain dopant activation anneal). In some embodiments, skipping the PCA process (e.g., which includes the deposition of TiN and Si or its compounds, a thermal anneal, and film removal) saves around $40-$60 per wafer, even with the addition of other processing stages disclosed herein (e.g., such as the nitridation anneal and addition of thin PWFM layer). In some embodiments, the nitridation anneal (e.g., performed at a temperature between about 800C-1250C, for about 0.1ms-10s, and with NH₃ soaking) serves at least two purposes: (1) maintaining the same thermal budget as the anneal of the PCA process used in other implementations, and (2) incorporating a percentage of nitrogen, N% into the gate oxide in a range between about 1%-5% to control capacitance equivalent thickness (CET) and improve RO speed. In some embodiments, the addition of a thin PWFM layer (e.g., having a thickness between about 1A-5A and including a transitional metallic compound such as TiN, TaN, TiP, TiSiN, TiWN, WCN, or other appropriate metallic compound), right before the NWFM layer deposition, provides for intermixing with the gate oxide, thereby preventing aluminum (Al) diffusion from NWFM layer and improving TDDB, a task previously accomplished by TiN capping and annealing (e.g., as part of the PCA process). In various embodiments, the disclosed methods may be applied to N-type GAA devices, P-type GAA devices, or both N-type and P-type GAA devices. By employing the methods disclosed herein, defects are reduced, device performance and reliability are increased, and RO speed is increased. Other embodiments and advantages will be evident to those skilled in the art upon reading the present disclosure.

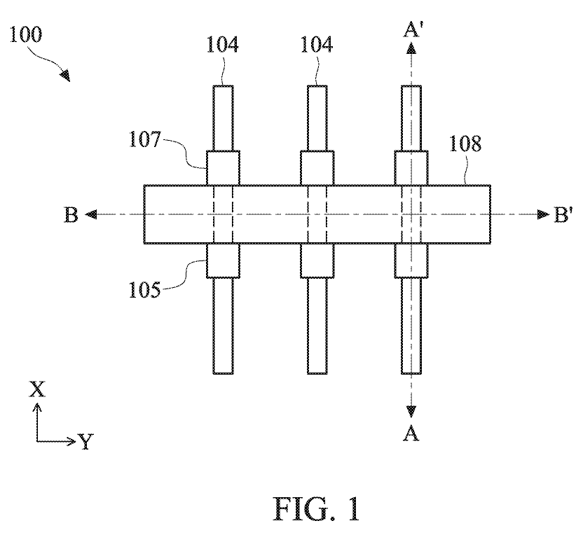

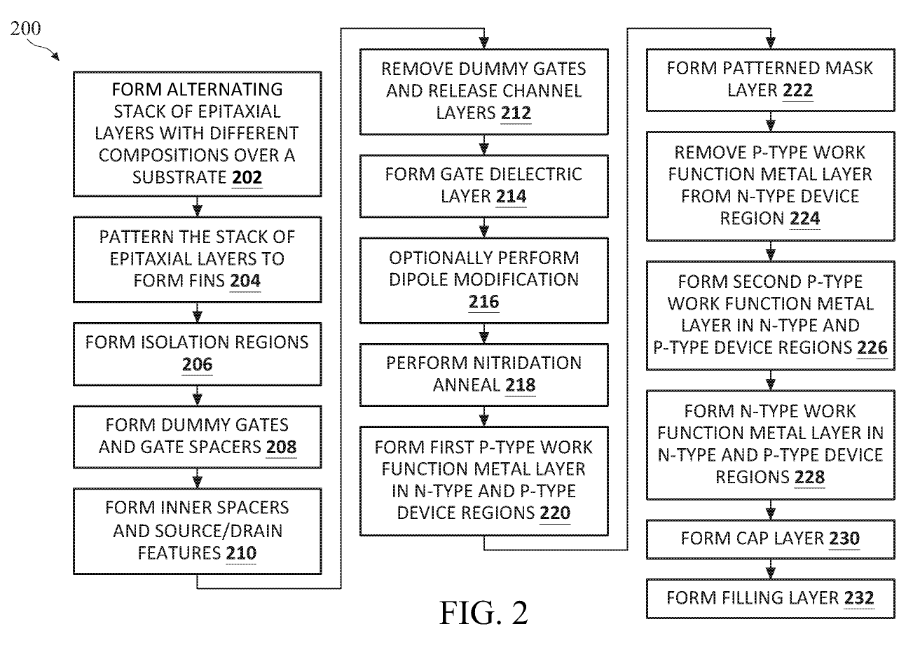

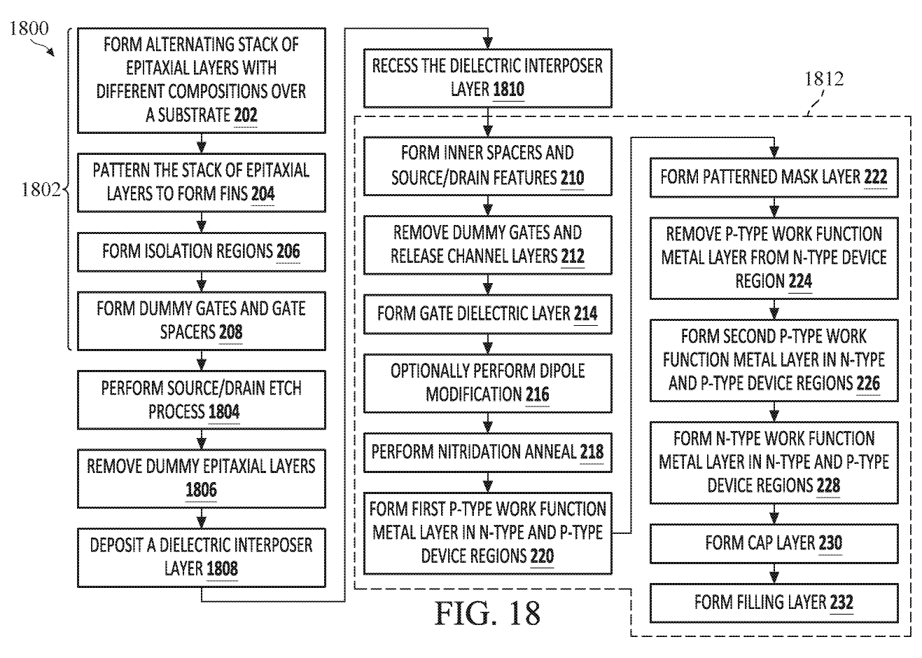

For purposes of the discussion that follows, FIG. 1 provides a simplified top-down layout view of a multi-gate device 100, which may include a GAA device, in some embodiments. The multi-gate device 100 may include a plurality of fins 104 extending from a substrate, a gate structure 108 disposed over and around the fins 104, and source/drain regions 105, 107, where the source/drain regions 105, 107 are formed in, on, and/or surrounding the fins 104. A channel region of the multi-gate device 100, which may include a plurality of nanostructured semiconductor channel layers (e.g., nanosheets/nanowires), is disposed within the fins 104, underlying the gate structure 108, along a plane substantially parallel to a plane defined by section A-A’ of FIG. 1. In some embodiments, sidewall spacers may also be formed on sidewalls of the gate structure 108. As shown, the fins 104 may be described as extending in a first direction (X), in the top-down view of FIG. 1, while the gate structure 108 (and sidewall spacers formed on sidewalls of the gate structure 108 may be described as extending in a second direction (Y), in the top-down view of FIG. 1. In some cases, the first direction (X) may be perpendicular to the second direction (Y). Various other features of the multi-gate device 100 are discussed in more detail below with reference to the methods of FIGS. 2 and 18.

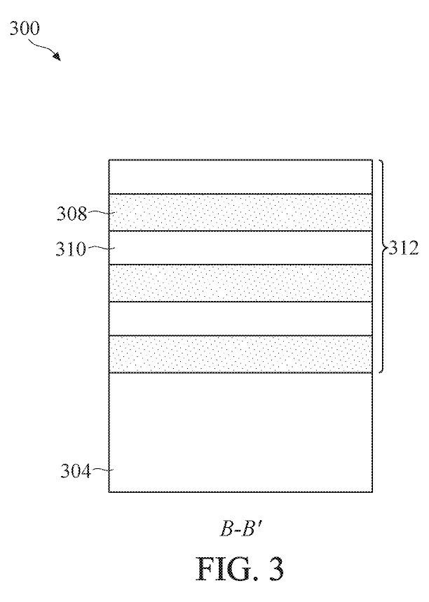

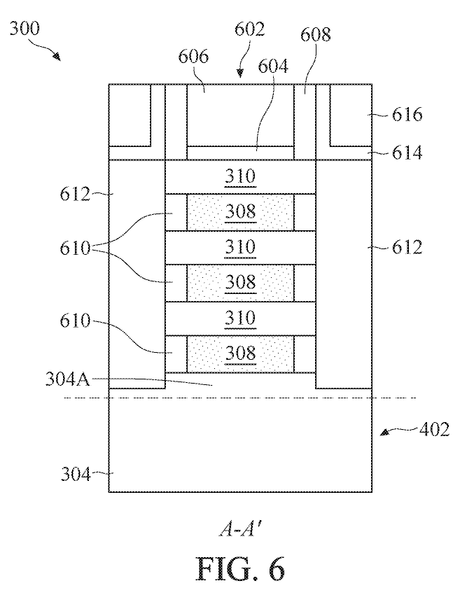

In accordance with various embodiments, formation of the disclosed GAA device may proceed according to different methods, such as described with reference to the methods of FIGS. 2 and 18. Referring first to FIG. 2, illustrated therein is a method 200 of semiconductor fabrication including fabrication of a semiconductor device 300 (e.g., which includes a multi-gate device), in accordance with various embodiments. The method 200 is discussed below with reference to FIGS. 3-15, 16A, 16B, 17A, and 17B, where FIGS. 6, 7, 17A, and 17B provide cross-sectional views of an embodiment of the semiconductor device 300 along a plane substantially parallel to a plane defined by section A-A’ of FIG. 1 (e.g., along the direction of a fin), and FIGS. 3-5, 8-15, 16A, and 16B provide cross-sectional views of an embodiment of the semiconductor device 300 along a plane substantially parallel to a plane defined by section B-B’ of FIG. 1 (e.g., along the direction of a gate structure). The method 200 is also discussed below with reference to fabrication of GAA transistors. However, it will be understood that aspects of the method 200 may be equally applied to other types of multi-gate devices, or to other types of devices implemented by the multi-gate devices, without departing from the scope of the present disclosure. In some embodiments, the method 200 may be used to fabricate the multi-gate device 100, described above with reference to FIG. 1. Thus, one or more aspects discussed above with reference to the multi-gate device 100 may also apply to the method 200. It is understood that the method 200 includes steps having features of a complementary metal-oxide-semiconductor (CMOS) technology process flow and thus, are only described briefly herein. Also, additional steps may be performed before, after, and/or during the method 200.

It is further noted that, in some embodiments, the semiconductor device 300 may include various other devices and features, such as other types of devices such as additional transistors, bipolar junction transistors, resistors, capacitors, inductors, diodes, fuses and/or other logic circuits, etc., but is simplified for a better understanding of the inventive concepts of the present disclosure. In some embodiments, the semiconductor device 300 include a plurality of semiconductor devices (e.g., transistors) which may be interconnected. Moreover, it is noted that the process steps of method 200, including any descriptions given with reference to the figures are merely exemplary and are not intended to be limiting beyond what is specifically recited in the claims that follow.

The method 200 begins at block 202 where an alternating stack of epitaxial layers with different compositions is formed over a substrate. Referring to the example of FIG. 3, in an embodiment of block 202, a substrate 304 is provided. In some embodiments, the substrate 304 may be a semiconductor substrate such as a silicon substrate. The substrate 304 may include various layers, including conductive or insulating layers formed on a semiconductor substrate. The substrate 304 may include various doping configurations depending on design requirements as is known in the art. The substrate 304 may also include other semiconductors such as germanium, silicon carbide (SiC), silicon germanium (SiGe), or diamond. Alternatively, the substrate 304 may include a compound semiconductor and/or an alloy semiconductor. Further, the substrate 304 may optionally include an epitaxial layer (epi-layer), may be strained for performance enhancement, may include a silicon-on-insulator (SOI) structure, and/or have other suitable enhancement features.

As shown in FIG. 3, epitaxial layers 308 of a first composition and epitaxial layers 310 of a second composition are alternately grown over the substrate 304 to provide a stack 312 of epitaxial layers 308, 310 over the substrate 304. For purposes of this discussion, the epitaxial layers 308 of the first composition include dummy layers (which may also be referred to as sacrificial layers), and the epitaxial layers 310 of the second composition include semiconductor channel layers. In an embodiment, the epitaxial layers 308 of the first composition include SiGe and the epitaxial layers of the second composition 310 include silicon (Si). It is also noted that while the epitaxial layers 308, 310 are shown as having a particular stacking sequence over the substrate 304, where the layer 310 is the topmost layer of the stack 312, other configurations are possible. For example, in some cases, the layer 308 may alternatively be the topmost layer of the stack 312. Stated another way, the order of growth for the epitaxial layers 308, 310, and thus their stacking sequence, may be switched or otherwise be different than what is shown in the figures, while remaining within the scope of the present disclosure.

As described in more detail below, the epitaxial layers 310 (e.g., including the second composition), or portions thereof, may form a channel region of a GAA transistor of the device 300. For example, as noted above, the epitaxial layers 310 may be referred to as semiconductor channel layers that are used to form a channel region of a GAA transistor. In various embodiments, the semiconductor channel layers (e.g., the layers 310 or portions thereof) may include various nanostructures such as nanosheet channel(s), nanowire channel(s), bar-shaped channel(s), and/or other suitable channel configurations. The semiconductor channel layers may also be used to form portions of the source/drain features of the GAA transistor, in some embodiments.

It is noted that while the device 300 is illustrated as including three (3) layers of the epitaxial layer 308 and three (3) layers of the epitaxial layer 310, this is for illustrative purposes only and not intended to be limiting beyond what is specifically recited in the claims. It can be appreciated that any number of epitaxial layers can be formed, where for example, the number of epitaxial layers depends on the desired number of semiconductor channel layers for the GAA transistor. In some embodiments, the number of epitaxial layers 310, and thus the number of semiconductor channel layers, is between 3 and 10.

In some embodiments, the epitaxial layers 308 (the dummy layers) each have a thickness in a range of about 5-15 nanometers (nm). In some cases, the epitaxial layers 310 (the semiconductor channel layers) each have a thickness in a range of about 5-15 nm. As noted above, the epitaxial layers 310 may serve as channel region(s) for a subsequently-formed multi-gate device (e.g., a GAA transistor) and its thickness may be chosen based at least in part on device performance considerations. The epitaxial layers 308 may serve to define a gap distance between adjacent channel region(s) for the subsequently-formed multi-gate device and its thickness may also be chosen based at least in part on device performance considerations.

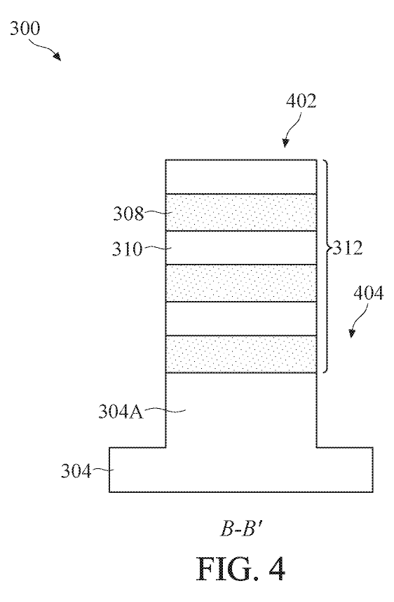

The method 200 proceeds to block 204 where the stack of epitaxial layers 308, 310 is patterned to form fins. With reference to the example of FIGS. 3 and 4, in an embodiment of block 204, a plurality of fins, such as fin 402, extending from the substrate 304 are formed. In various embodiments, each of the fins includes a substrate portion 304A (or mesa 304A) formed from the substrate 304, portions of the epitaxial layers 308 of the first composition, and portions of the epitaxial layers 310 of the second composition. In some embodiments, the fin 402 extends along a first direction (e.g., an X-direction), similar to the fins 104 shown in the example of FIG. 1.

The fins 402 may be fabricated using suitable processes including photolithography and etch processes. The photolithography process may include forming a photoresist layer over the device 300, exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 304, and layers formed thereupon, while an etch process forms trenches 404 in unprotected regions through the epitaxial layers 308, 310, and into the substrate 304, thereby leaving the plurality of extending fins 402. The trenches 404 may be etched using a dry etch (e.g., reactive ion etching), a wet etch, and/or other suitable processes. Numerous other embodiments of methods to form the fins 402 on the substrate 304 may also be used. As described in more detail below, and in some embodiments, the portions of the epitaxial layers 310 of the second composition will serve as a GAA device channel.

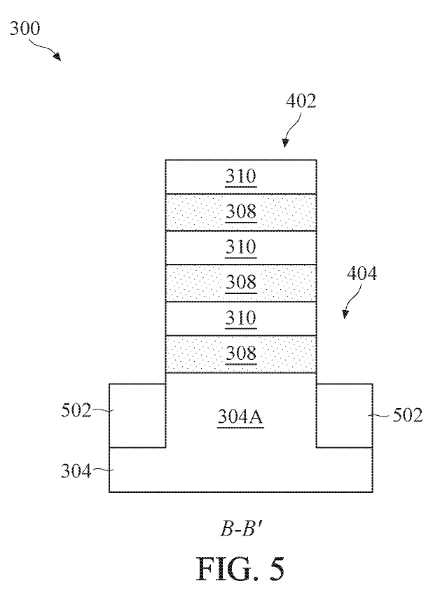

The method 200 then proceeds to block 206 where isolation regions are formed. With reference to the example of FIGS. 4 and 5, in an embodiment of block 206, isolation regions 502 are formed on either side of the fins (e.g., such as the fin 402) to isolate neighboring fins from each other. In some embodiments, the isolation regions 502 may include shallow trench isolation (STI) features. Formation of the isolation regions 502 includes filling the trenches 404 with a dielectric layer, where the dielectric layer may include SiO₂, silicon nitride, silicon oxynitride, fluorine-doped silicate glass (FSG), a low-K dielectric, combinations thereof, and/or other suitable materials known in the art. In various examples, the dielectric layer may be deposited by a CVD process, a subatmospheric CVD (SACVD) process, a flowable CVD process, an ALD process, a PVD process, or other suitable process. In some embodiments, after deposition of the dielectric layer, the device 300 may be annealed to improve the quality of the dielectric layer. In some embodiments, a field oxide, a LOCOS feature, and/or other suitable isolation features may additionally or alternatively be implemented on and/or within the substrate 304. However, other embodiments are possible. For example, in some embodiments, the dielectric layer used to form the isolation regions 502 may include a multi-layer structure, for example, having one or more liner layers. After deposition of the dielectric layer, a chemical mechanical planarization (CMP) process may be performed and the dielectric layer may be recessed, resulting in the isolation regions 502 as shown in FIG. 5. By way of example, the dielectric layer used to form the isolation regions 502 may be recessed to laterally expose the epitaxial layers 308, 310. In some embodiments, the recessing process may include a dry etching process, a wet etching process, and/or a combination thereof. It is also noted that in various embodiments, a top surface of the isolation regions 502 may be lower than, or coplanar with, a top surface of the substrate portion 304A.

The method 200 then proceeds to block 208 where dummy gates and gate spacers are formed. With reference to the example of FIG. 6, in an embodiment of block 208, a dummy gate 602 is formed over the fin 402. In some embodiments, the dummy gate 602 extends along a second direction (e.g., a Y-direction), similar to the gate structure 108 shown in the example of FIG. 1. The second direction in which the dummy gate 602 extends is different than the first direction in which the fin 402 extends. In some examples, the dummy gate 602 extends in a direction perpendicular to the fin 402. As discussed below, the dummy gate 602 is subsequently removed and replaced by a final gate stack at a subsequent processing stage of the device 300. For example, the dummy gate 602 may be replaced at a later processing stage by a high-K dielectric layer (HK) and metal gate electrode (MG). While the present discussion is directed to a replacement gate (gate-last) process whereby a dummy gate structure is formed and subsequently replaced, other configurations may be possible (e.g., such as a gate-first process). The portion of the fin 402 underlying the dummy gate 602 may be referred to as the channel region of the device 300. The dummy gate 602 may also define a source/drain region of the fin 402, for example, as the regions of the fin 402 adjacent to and on opposing sides of the channel region.

In some embodiments, the dummy gate 602 includes a dielectric layer 604 and an electrode layer 606 over the dielectric layer 604. In some embodiments, one or more hard mask layers (e.g., such as a nitride layer and/or an oxide layer) may also be formed over the dummy gate 602. In some embodiments, the dielectric layer 604 includes silicon oxide. Alternatively, or additionally, the dielectric layer 604 may include silicon nitride, a high-K dielectric material or other suitable material. In some embodiments, the electrode layer 606 may include polycrystalline silicon (polysilicon).

After formation of the dummy gate 602, and in a further embodiment of block 208, gate spacers 608 may be formed on sidewalls of the dummy gate 602. In some cases, the gate spacers 608 may include a dielectric material such as silicon oxide, silicon nitride, silicon carbide, silicon oxynitride, SiCN, silicon oxycarbide, SiOCN, a low-K material (e.g., with a dielectric constant ‘k’ < 7), and/or combinations thereof. In particular, the dielectric constant of the gate spacers 608 is less than a dielectric constant of a gate dielectric layer 806, as described in more detail below and which forms part of a final gate structure of the device 300. In some embodiments, the gate spacers 608 may include main spacer layers, liner layers, and the like, as well as other spacer layers. By way of example, the gate spacers 608 may be formed by conformally depositing a dielectric material over the device 300 using processes such as a CVD process, a subatmospheric CVD (SACVD) process, a flowable CVD process, an ALD process, a PVD process, or other suitable process, and selectively etching portions of the dielectric material such that the gate spacers 608 remain on the sidewalls of the dummy gate 602.

The method 200 then proceeds to block 210 where inner spacers and source/drain features are formed. Still referring to the example of FIG. 6, in an embodiment of block 210, a source/drain etch process is initially performed to the device 300 to remove portions of epitaxial layers 308, 310 in source/drain regions of the device 300 (e.g., adjacent to and on either side of the dummy gate 602) to form trenches which expose underlying portions of the substrate 304. The source/drain etch process also serves to expose lateral surfaces of the epitaxial layers 308, 310. By way of example, the source/drain etch process may include a dry etching process, a wet etching process, and/or a combination thereof.

After the source/drain etch process, a dummy layer recess process is performed to the device 300. The dummy layer recess process includes a lateral etch of the epitaxial layers 308 (the dummy layers) to form recesses along sidewalls of the previously formed trenches. In some embodiments, the dummy layer recess process is performed using a dry etching process, a wet etching process, and/or a combination thereof. In some cases, the dummy layer recess process may include etching using a standard clean 1 (SC-1) solution, ozone (O₃), a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch.

After the dummy layer recess process, an inner spacer material is deposited over the device 300, within the trenches (e.g., formed by the source/drain etch process) and within the recesses (e.g., formed by the dummy layer recess process). In some embodiments, the inner spacer material may include amorphous silicon. In some examples, the inner spacer material may include a dielectric material such as silicon oxide, silicon nitride, silicon carbide, silicon oxynitride, SiCN, silicon oxycarbide, SiOCN, a low-K material (e.g., with a dielectric constant ‘k’ < 7), and/or combinations thereof. By way of example, the inner spacer material may be formed by conformally depositing the inner spacer material over the device 300 using processes such as a CVD process, a subatmospheric CVD (SACVD) process, a flowable CVD process, an ALD process, a PVD process, or other suitable process.

After deposition of the inner spacer material, an inner spacer etch-back process is performed to etch the inner spacer material from over the device 300 and along sidewalls of the trenches (e.g., formed by the source/drain etch process), while the inner spacer material remains disposed within the recesses (e.g., formed by the dummy layer recess process), thereby providing inner spacers 610 for the device 300. As shown in FIG. 6, the inner spacers 610 are formed in contact with (or interfacing) the recessed epitaxial layers 308 (the dummy layers). The inner spacer etch-back process used to form the inner spacers 610 may include a wet etch process, a dry etch process, or a combination thereof. In some cases, any residual portions of the inner spacer material that remain on top surfaces of the device 300 and/or on sidewalls or bottom surfaces of the trenches (e.g., formed by the source/drain etch process), for example after the inner spacer etch-back process, may be removed during a subsequent clean process (e.g., prior to epitaxial growth of source/drain features). In various examples, the inner spacers 610 may extend beneath the gate spacers 608 (formed on sidewalls of the dummy gate 602) while being disposed adjacent to subsequently formed source/drain features, as described below. In some cases, the inner spacers 610 may extend at least partially beneath the dummy gate 602. Notably, the formation of the inner spacers 610, including respective manufacturing steps described above, may be optional. That is, the formation of the inner spacers 610 may be omitted, and the inner spacers 610 may not exist in the final structure of the device 300, in some embodiments.

After formation of the inner spacers 610, source/drain features 612 are formed in the source/drain regions adjacent to and on either side of the dummy gate 602 of the device 300. For example, the source/drain features 612 may be formed within the trenches (e.g., formed by the source/drain etch process) of the device 300, over the exposed portions of the substrate 304 and in contact with (or interfacing) the adjacent inner spacers 610 and the semiconductor channel layers (the epitaxial layers 310) of the device 300. In some embodiments, a clean process may be performed immediately prior to formation of the source/drain features 612 to remove any residual portions of inner spacer material, as previously noted. The clean process may include a wet etch, a dry etch, or a combination thereof. It is also noted that the term “source/drain features” may refer to a source or a drain, individually or collectively dependent upon the context.

In some embodiments, the source/drain features 612 are formed by epitaxially growing a semiconductor material layer in the source/drain regions. In various embodiments, the semiconductor material layer grown to form the source/drain features 612 may include Ge, Si, GaAs, AlGaAs, SiGe, GaAsP, SiP, or other suitable material. The source/drain features 612 may be formed by one or more epitaxial (epi) processes. In some embodiments, the source/drain features 612 may be in-situ doped during the epi process. For example, in some embodiments, epitaxially grown SiGe source/drain features may be doped with boron. In some cases, epitaxially grown Si epi source/drain features may be doped with carbon to form Si:C source/drain features, phosphorous to form Si:P source/drain features, or both carbon and phosphorous to form SiCP source/drain features. In some embodiments, the source/drain features 612 are not in-situ doped, and instead an implantation process is performed to dope the source/drain features 612. It is also noted that the source/drain features 612 may be formed separately for N-type and P-type devices which may use different epitaxial layers and/or dopants, and which may be formed in separate N-type and P-type device regions of the substrate 304. In addition, and in some embodiments, a source/drain dopant activation anneal process may be performed after introduction of dopants (e.g., such as by in-situ doping and/or an implantation process) into the source/drain features 612. In some existing implementations, the source/drain dopant activation anneal process may be performed for a duration of between about 0.1ms to about 10s and at a temperature in a range between about 900-1,000 degrees Celsius. However, in accordance with embodiments of the present disclosure, the source/drain dopant activation anneal process is fine-tuned to enhance the efficacy of the anneal process and thereby enhance performance of the device 300. For example, in some embodiments, the source/drain dopant activation anneal process may be performed for a duration of between about 0.1ms to about 10s and at a temperature in a range between about 1,050-1,200 degrees Celsius. Such fine-tuning may be alternatively described as fine-tuning of MEOL thermal processing, in some cases.

After forming the source/drain features 612, and in some embodiments, a contact etch stop layer (CESL) 614 may be conformally formed over the device 300. In some examples, the CESL 614 may include a silicon nitride layer, silicon oxide layer, a silicon oxynitride layer, and/or other materials known in the art. In some embodiments, an inter-layer dielectric (ILD) layer 616 may be formed over the CESL 614, as shown in FIG. 6. In various cases, the ILD layer 616 may include materials such as tetraethylorthosilicate (TEOS) oxide, un-doped silicate glass, or doped silicon oxide such as borophosphosilicate glass (BPSG), fluorosilicate glass (FSG), phosphosilicate glass (PSG), boron doped silicon glass (BSG), and/or other suitable dielectric materials. In some cases, the CESL 614 and the ILD layer 616 are composed of different materials. In some embodiments, after formation of the ILD layer 616, the device 300 may be subject to a high thermal budget process to anneal the ILD layer 616. In some embodiments, after formation of the CESL 614 and the ILD layer 616, a CMP process may be performed to remove portions of the ILD layer 616 and the CESL 614 overlying the dummy gate 602, as well as any hard mask layers overlying the dummy gate 602 that may be present, to planarize a top surface of the device 300 and expose a top surface of the electrode layer 606.

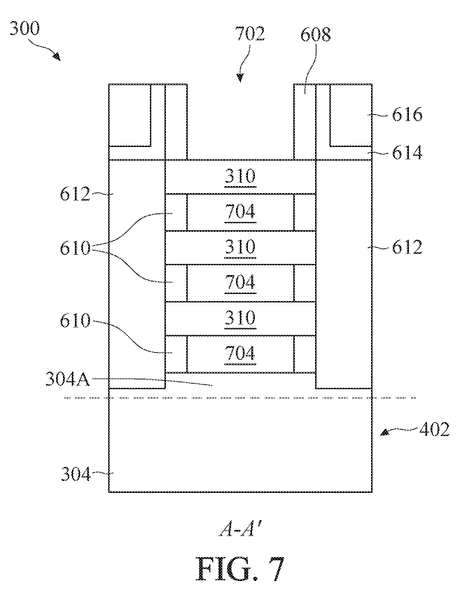

The method 200 then proceeds to block 212 where dummy gates are removed (e.g., as part of an RPG process) and a channel layer release process is performed. Referring to the example of FIGS. 6 and 7, in an embodiment of block 212, the electrode layer 606 of the dummy gate 602 (e.g., exposed by the CMP process, as noted above) may initially be removed by suitable etching processes to form a trench 702 that exposes the dielectric layer 604. Thereafter, in some embodiments, an etching process may be performed to remove the exposed dielectric layer 604 from the trench 702. In some examples, the etching processes used to remove the electrode layer 606 and the dielectric layer 604 may include a wet etch, a dry etch, or a combination thereof.

After removal of the electrode layer 606 and the dielectric layer 604, and in a further embodiment of block 212, the dummy layers (the epitaxial layers 308) in the channel region of the device 300 may be selectively removed (e.g., using a selective etching process), while the semiconductor channel layers (the epitaxial layers 310) remain substantially unetched. In some examples, selective removal of the dummy layers (the epitaxial layers 308) may be referred to as a channel layer release process (e.g., as the semiconductor channel layers are released from the dummy layers). The selective etching process may be performed through the trench 702 provided by the removal of the dummy gate 602. In some embodiments, the selective etching process may include a selective wet etching process. In some cases, the selective wet etching includes ammonia and/or ozone. As merely one example, the selective wet etching process includes tetra-methyl ammonium hydroxide (TMAH). In some embodiments, the selective etching process may include a dry, plasma-free etching process.

It is noted that as a result of the selective removal of the dummy layers (the epitaxial layers 308), gaps 704 are formed between the adjacent semiconductor channel layers (the epitaxial layers 310) in the channel region. By way of example, the gaps 704 may serve to expose first portions of the epitaxial layers 310 between opposing inner spacers 610, while second portions of the epitaxial layers 310 remain covered by the inner spacers 610. As described in more detail below, portions of gate structures (e.g., including a metal gate stack having an interfacial layer, a high-K dielectric layer, and one or more metal electrode layers) will be formed within the gaps 704 between adjacent semiconductor channel layers (the epitaxial layers 310) and in contact with (or interfacing) the inner spacers 610.

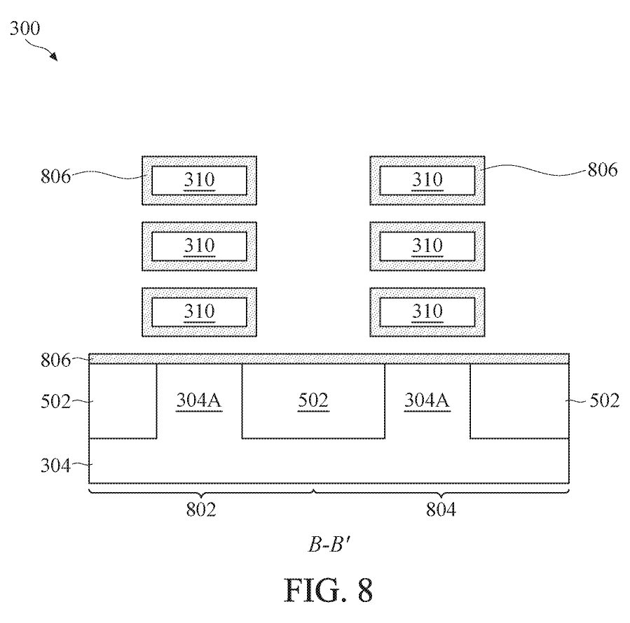

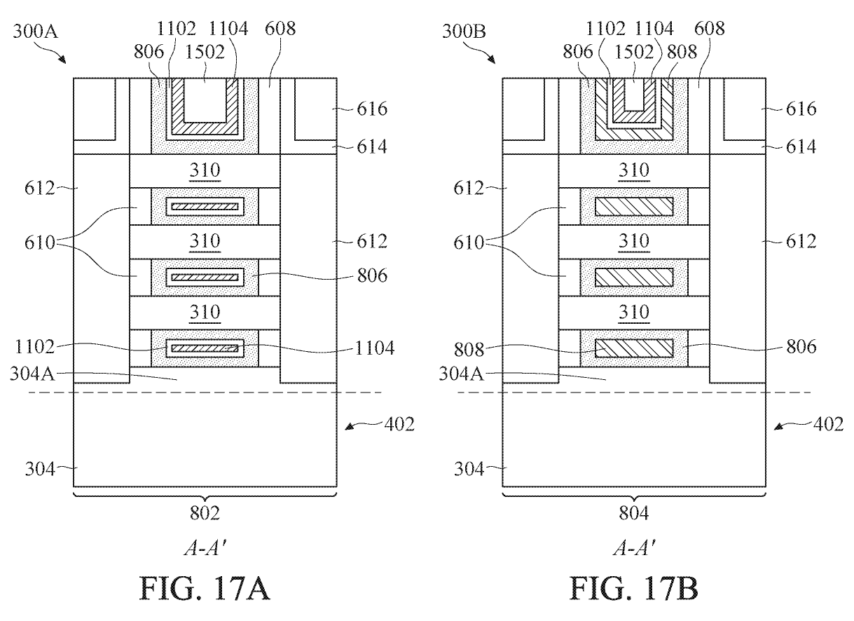

The method 200, as discussed above and including blocks 202-212, is largely applicable to both N-type and P-type GAA devices. To be sure, it has been noted that the source/drain features 612 may be formed (at block 210) separately for N-type and P-type devices. In the remaining discussion of the method 200 that follows, the description of blocks 214-232 and related FIGS. 8-15, 16A, 16B, 17A, and 17B will more specifically differentiate processes performed in each of N-type and P-type device regions of the substrate 304. To that end, FIGS. 8-15, 16A, and 16B illustrate an N-type device region 802 and a P-type device region 804 of the device 300, and FIGS. 17A and 17B illustrate alternative views of a final device structure for an N-type device formed in the N-type device region 802 and for a P-type device formed in the P-type device region 804, respectively. In addition, FIGS. 8-15, 16A, and 16B provide cross-sectional views of an embodiment of the semiconductor device 300 along a plane substantially parallel to a plane defined by section B-B’ of FIG. 1 (e.g., along the direction of a gate structure), and FIGS. 17A and 17B provide cross-sectional views of an embodiment of the semiconductor device 300 along a plane substantially parallel to a plane defined by section A-A’ of FIG. 1 (e.g., along the direction of a fin).

After the dummy gates are removed and the channel layer release process is performed (block 212), the method 200 proceeds to block 214 where, as a first step of formation of a gate structure, a gate dielectric layer is formed in both N-type and P-type device regions of the substrate 304. As discussed in more detail below, the gate structure to be formed may include a high-K/metal gate stack, however other compositions are possible. In some embodiments, the gate structure to be formed may provide the gate associated with the multi-channels provided by the plurality of exposed semiconductor channel layers (the exposed epitaxial layers 310, now having gaps 704 therebetween) in the channel region of the device 300. In an embodiment of block 214, and with reference to the example of FIG. 8, a gate dielectric layer 806 is formed wrapping around the exposed surfaces of the epitaxial layers 310 (semiconductor channel layers), in the illustrated cross-sectional view, in each of the N-type and P-type device regions 802, 804, including on the exposed first portions of the epitaxial layers 310 within the gaps 704 and between opposing inner spacers 610 (see FIG. 7), over the substrate portion 304A (or mesa 304A), over the isolation regions 502, and along exposed sidewalls of the gate spacers 608 (see FIGS. 7 and 17A/17B). In some embodiments, the gate dielectric layer 806 includes a high-K dielectric layer. In some embodiments, prior to forming the high-K dielectric layer, an interfacial layer (IL) may be formed, and the high-K dielectric layer is then formed over the IL. In various embodiments, the IL may be part of the gate dielectric layer 806 such that the IL and the high-K dielectric layer may collectively define a gate dielectric of the gate structure for the device 300. In some embodiments, a thickness of the high-K dielectric layer may be in a range between about 1-2 nm. In some examples, a total thickness of the gate dielectric (including both the IL and the high-K dielectric layer) may be in a range between about 1-2 nm. High-K gate dielectrics, as used and described herein, include dielectric materials having a high dielectric constant, for example, greater than that of thermal silicon oxide (~3.9).

In an example, the IL may include a dielectric material such as silicon oxide (SiO₂), HfSiO, or silicon oxynitride (SiON). In some embodiments, the high-K dielectric layer may include hafnium oxide (HfO₂). Alternatively, the high-K dielectric layer may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. As previously noted, the gate dielectric layer 806 has a greater dielectric constant than the gate spacers 608. Additionally, in some embodiments, the gate dielectric layer 806 may have a dielectric constant that is at least two times greater than a dielectric constant of the ILD layer 616, previously discussed. In various embodiments, the gate dielectric layer 806 may be formed by thermal oxidation, ALD, physical vapor deposition (PVD), pulsed laser deposition (PLD), CVD, and/or other suitable methods.

After forming the gate dielectric layer 806, the method 200 proceeds to block 216 where a dipole modification process is optionally performed. For example, in some embodiments, the dipole modification process may be used to modulate a transistor threshold voltage (Vt) by tuning a work function (WF) of the transistor. For instance, a dipole inducing layer may be formed over the gate dielectric layer 806 in one or both of the N-type and P-type device regions 802, 804. If dipole modification is to be performed in only one of the N-type and P-type device regions 802, 804, a patterned hard mask (e.g., which may include an Al-containing hard mask) may be formed to expose one of the N-type and P-type device regions 802, 804, while the other one of the N-type and P-type device regions 802, 804 remains covered by the patterned hard mask. In some embodiments, the dipole inducing layer may include Al, Zn, Nb, La, Y, Mg, Sr, Lu, Er-oxide, nitride, carbide or a combination thereof. After forming the dipole inducing layer in one or both of the N-type and P-type regions 802, 804, atoms of the dipole inducing layer may be driven into the gate dielectric layer 806 using an annealing process. As a result, and in some embodiments, a dipole may be formed at an interface between the high-K dielectric layer and the IL of the gate dielectric layer 806. The dipole formed, in turn, will modulate the transistor WF and Vt and can help to enhance device performance. In some cases, the annealing process of the dipole modification process may also cause Al atoms from the patterned hard mask to diffuse into the gate dielectric layer 806 of devices covered by the patterned hard mask. In various embodiments, after formation of the dipole within the gate dielectric layer 806, any remaining material of the dipole-inducing layer (as well as the patterned hard mask, if used) may be removed prior to subsequent processing. For avoidance of doubt, in some cases, the dipole modification process (block 216) may be omitted if WF/Vt tuning is not desired. It is noted that in some existing implementations, the PCA process may be performed after the dipole modification process. However, in accordance with embodiments of the present disclosure, skipping the PCA process (which includes a film removal step) after the dipole modification process reduces loss of portions of the gate dielectric layer 806 and thus prevents the loss of dipole incorporation provided by the dipole modification process. In some cases, skipping the PCA process also minimizes or prevents further diffusion of Al atoms from the patterned hard mask into the gate dielectric layer 806 (of devices covered by the patterned hard mask) and/or further diffusion of Al atoms previously introduced into the gate dielectric layer 806 (e.g., by the annealing process of the dipole modification process) deeper into the gate dielectric layer 806.

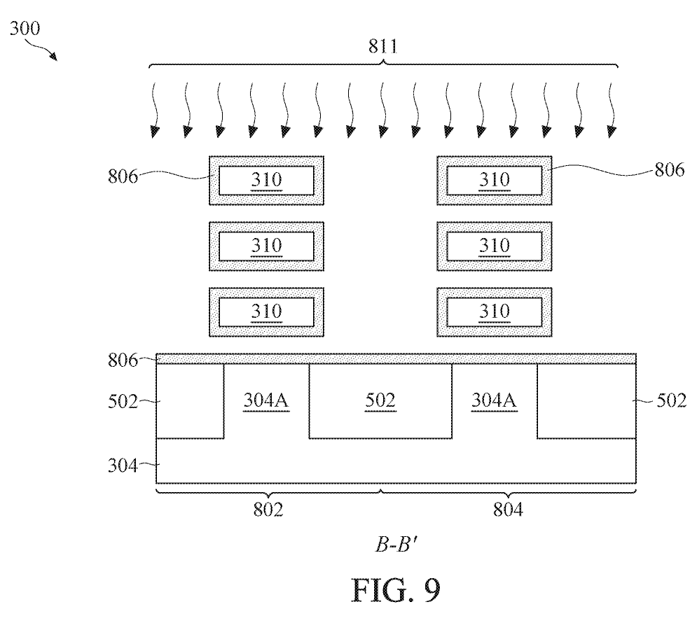

Instead of next performing a PCA process, the method 200 proceeds to block 218 where a nitridation anneal is performed. Referring to the example of FIG. 9, in an embodiment of block 218, a the nitridation anneal 811 may be performed to the entire device 300, including to both the N-type and P-type device regions 802, 804. By way of example, the nitridation anneal 811 is performed by introducing (flowing) a nitrogen-containing gas (e.g., such as NH₃, N₂, other nitrogen-containing gas, or a combination thereof) into a process chamber including the device 300 while an anneal process is performed. Thus, the nitridation anneal 811 is performed in a nitrogen-containing gas ambient. In some embodiments, the anneal process may be performed at a temperature in a range between about 800C-1250C. It is noted that if the temperature of the anneal process is too high, there is a risk of Si (e.g., the epitaxial layers 310) melting. On the other hand, if the temperature of the anneal process is too low, there may not be enough nitrogen diffusion into the gate dielectric layer 806 (e.g. nitrogen may be incorporated into high-K dielectric layer but not the IL), which would be detrimental for the source/drain features 612 (e.g., at least at the N-type device region 802). In some cases, the nitridation anneal 811 is performed for about 0.1ms-10s. Generally, and in various examples, nitrogen introduced by the nitridation anneal 811 may diffuse into both the high-K dielectric layer and the IL of the gate dielectric layer 806. In some embodiments, a percentage of nitrogen, N% incorporated into the gate dielectric layer 806 may be in a range between about 1%-5%. As a result of the nitrogen incorporation by the nitridation anneal 811, and in some cases, CET and RO speed of the device 300 may be improved.

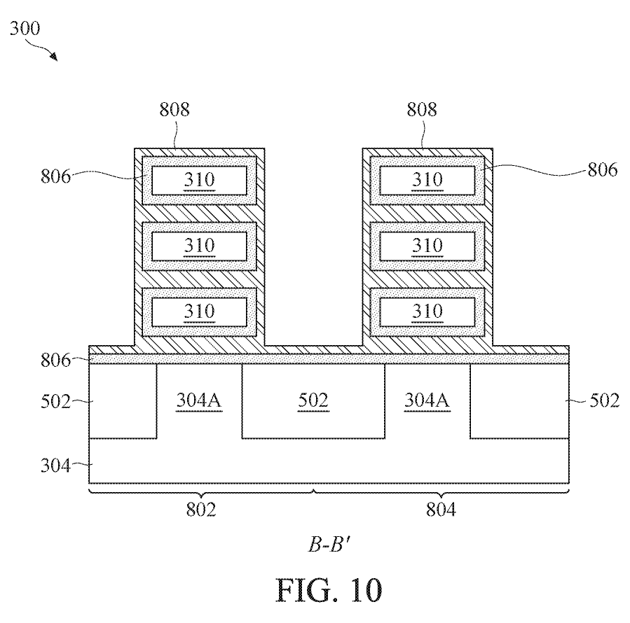

After the nitridation anneal, the method 200 proceeds to block 220 where a first P-type work function metal (PWFM) layer is formed. With reference to the example of FIG. 10, in an embodiment of block 220, a first PWFM layer 808 is formed over the gate dielectric layer 806 in each of the N-type and P-type device regions 802, 804, wrapping around each of the epitaxial layers 310 in each of the N-type and P-type device regions 802, 804. In some embodiments, the first PWFM layer 808 may include substantially Al-free (e.g., with no Al) (i) Ti-based nitrides or alloys, such as TiN, TiSiN, titanium gold (Ti—Au) alloy, titanium copper (Ti—Cu) alloy, titanium chromium (Ti—Cr) alloy, titanium cobalt (Ti—Co) alloy, titanium molybdenum (Ti—Mo) alloy, or titanium nickel (Ti—Ni) alloy; (ii) Ta-based nitrides or alloys, such as TaN, TaSiN, Ta—Au alloy, Ta—Cu alloy, Ta—W alloy, tantalum platinum (Ta—Pt) alloy, Ta—Mo alloy, Ta—Ti alloy, or Ta—Ni alloy; or (iii) a combination thereof. In some examples, the first PWFM 808 layer may have a thickness in a range between about 20-40 Angstroms. In some embodiments, the first PWFM 808 layer may be formed by ALD, PVD, PLD, CVD, and/or other suitable methods.

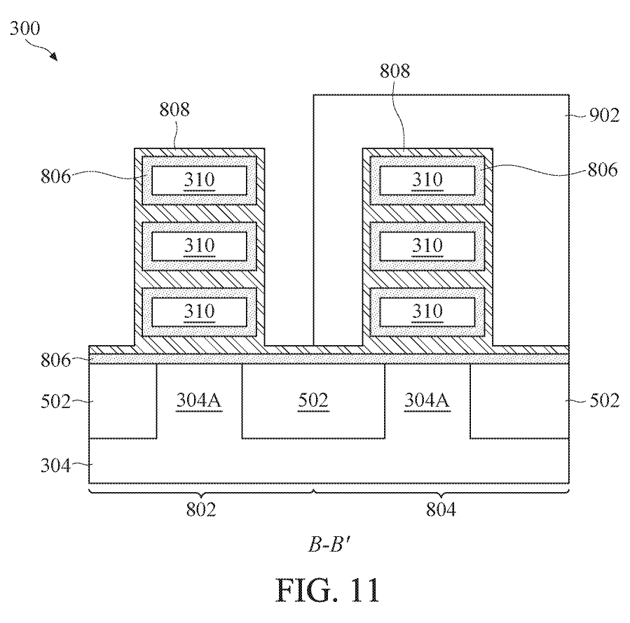

After forming the first PWFM layer 808, the method 200 proceeds to block 222 where a patterned mask layer is formed. With reference to the example of FIG. 11, in an embodiment of block 222, a patterned mask layer 902 is formed over the P-type device region 804. Initially, the material used to form the patterned mask layer 902 may be formed over the entire device 300, including over the N-type and P-type device regions 802, 804. In some embodiments, the material used to form the patterned mask layer 902 may include an inorganic material or an organic material (e.g., such as a polymer) and may be deposited by ALD, CVD, spin-coating, or other suitable process. In some examples, the mask layer 902 may include a bottom anti-reflective coating (BARC) layer. By way of example, the material used to form the patterned mask layer 902 may be patterned using appropriate photolithography and etching processes, thereby providing the patterned mask layer 902, as shown in FIG. 11.

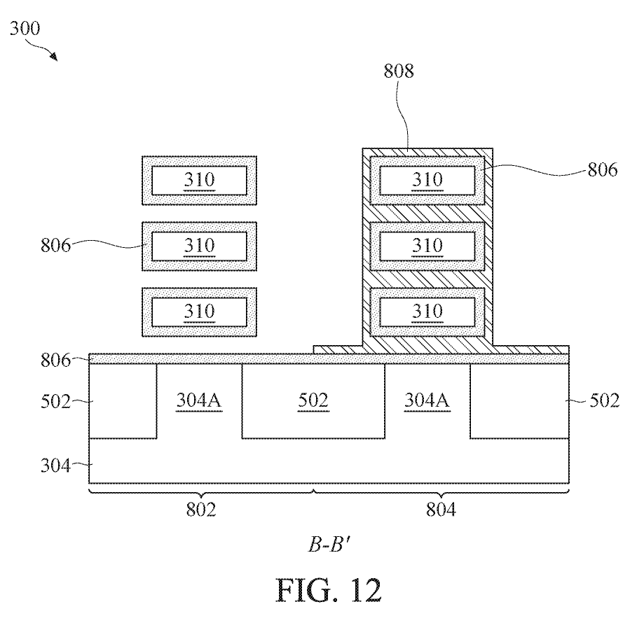

The method 200 then proceeds to block 224 where the first PWFM layer 808 is removed from the N-type device region 802. With reference to the example of FIGS. 11 and 12, in an embodiment of block 224, an etching process may be performed to remove the first PWFM 808 from the N-type device region 802 and expose the underlying gate dielectric layer 806, while the P-type device region 804 remains protected by the patterned mask layer 902. As a result, the first PWFM 808 remains unetched in the P-type device region 804. In some embodiments, the etching process used to remove the first PWFM 808 from the N-type device region 802 may include a wet etch, a dry etch, or a combination thereof. In some embodiments, and due to the limited space between adjacent semiconductor channel layers (the epitaxial layers 310), (i) at least some of the first PWFM 808 may remain disposed within the gap between adjacent semiconductor channel layers, and/or (ii) portions of the gate dielectric layer 806 disposed between adjacent semiconductor channel layers may be thinner than portions of the gate dielectric layer 806 disposed in regions outside the space between adjacent semiconductor channel layers. By way of example, after removal of the first PWFM 808 from the N-type device region 802, the patterned mask layer 902 may be removed (e.g., using a wet etch, a dry etch, or a combination thereof).

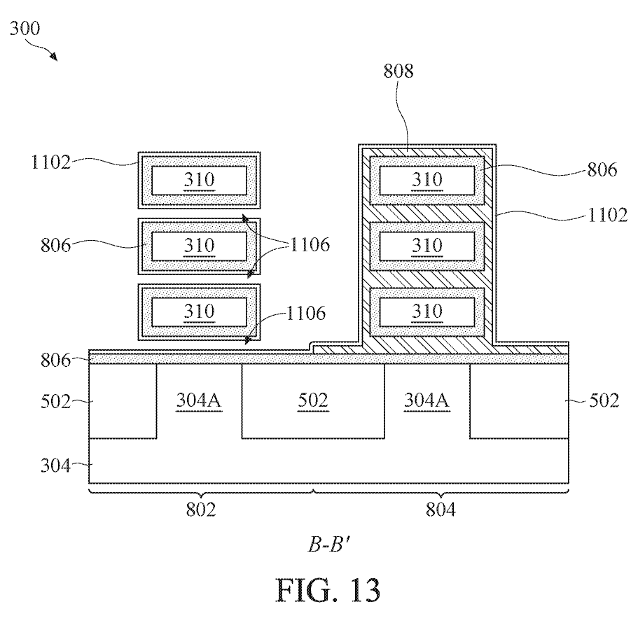

After removing the first PWFM 808 from the N-type device region 802, the method 200 proceeds to block 226 where a second PWFM layer is formed in each of the N-type and P-type device regions 802, 804. In various embodiments, the second PWFM provides a thin PWFM layer that is deposited right before deposition of an N-type work function metal (NWFM) layer, discussed in more detail below. With reference to the example of FIGS. 12 and 13, in an embodiment of block 226, a second PWFM layer 1102 may be formed over the gate dielectric layer 806 in the N-type device region 802 and over the first PWFM layer 808 in the P-type device region 804. In particular, the second PWFM layer 1102 surrounds (or wraps around) each of the epitaxial layers 310 (semiconductor channel layers) in the N-type device region 802, and the second PWFM layer 1102 is also formed over the substrate portion 304A (or mesa 304A) and the isolation regions 502 in the N-type device region 802. In some embodiments, the second PWFM layer 1102 may include a transitional metallic compound such as TiN, TaN, TiP, TiSiN, TiWN, WCN, or other metallic compounds. More generally, in some cases and like the first PWFM layer 808, the second PWFM layer 1102 may include substantially Al-free (e.g., with no Al) (i) Ti-based nitrides or alloys, such as TiN, TiSiN, titanium gold (Ti—Au) alloy, titanium copper (Ti—Cu) alloy, titanium chromium (Ti—Cr) alloy, titanium cobalt (Ti—Co) alloy, titanium molybdenum (Ti—Mo) alloy, or titanium nickel (Ti—Ni) alloy; (ii) Ta-based nitrides or alloys, such as TaN, TaSiN, Ta—Au alloy, Ta—Cu alloy, Ta—W alloy, tantalum platinum (Ta—Pt) alloy, Ta—Mo alloy, Ta—Ti alloy, or Ta—Ni alloy; or (iii) a combination thereof. Additionally, and in some embodiments, the first PWFM layer 808 and the second PWFM layer 1102 may be composed of a same material. Alternatively, in some cases, the first PWFM layer 808 and the second PWFM layer 1102 may be composed of different materials.

In accordance with embodiments of the present disclosure, the second PWFM layer 1102 may serve as a blocking layer. More particularly, and in some embodiments, the second PWFM layer 1102 may serve to prevent diffusion of aluminum (Al). Thus, in some examples, the second PWFM layer 1102 may be referred to as an aluminum-blocking layer. In some cases, the second PWFM layer 1102 may at least partially intermix with the gate dielectric layer 806 (e.g., at least in the N-type device region 802) and prevent aluminum (Al) diffusion from the NWFM layer 1104, deposited during a subsequent processing step. In some embodiments, such intermixing may form an intermix layer at a boundary between the gate dielectric layer 806 and the second PWFM layer 1102. Generally, and in accordance with embodiments of the present disclosure, the nitridation anneal (block 218) and the blocking layer (the second PWFM layer 1102) may serve to decrease and/or prevent diffusion of aluminum (Al) into the gate dielectric 806 by incorporation of nitrogen (e.g., within the gate dielectric 806) and titanium (e.g., at or near the interface between the gate dielectric 806 and the second PWFM layer 1102). It is also noted that in various examples, the second PWFM 1102 layer may be thinner than the first PWFM 808. In some cases, the second PWFM 1102 may have a thickness in a range between about 1-5 Angstroms. Thus, in some embodiments, a ratio between a thickness of the first PWFM layer 808 and the second PWFM layer 1102 may be in a range between about 4-40. In some embodiments, the second PWFM layer 1102 may be formed by ALD, PVD, PLD, CVD, and/or other suitable methods.

As shown, and due to the small thickness of the second PWFM layer 1102, the second PWFM layer 1102 formed over a particular epitaxial layer 310 (semiconductor channel layer) does not merge with the second PWFM layer 1102 formed on an adjacent epitaxial layer 310 (adjacent semiconductor channel layer). As a result, there remains a space 1106 (or gap 1106) between portions of the second PWFM layer 1102 formed on opposing surfaces of adjacent semiconductor channel layers and between the bottommost epitaxial layer 310 (bottommost semiconductor channel layer) and the substrate portion 304A (or mesa 304A). In addition, and in some embodiments, the thickness of the second PWFM layer 1102 may be uniform. However, in some cases, the second PWFM layer 1102 may be thicker in regions outside the space between adjacent semiconductor channel layers (adjacent epitaxial layers 310) as compared to regions between adjacent semiconductor channel layers. In some examples, such variation in thickness may be due to suboptimal diffusion of material (used to form the second PWFM layer 1102) within the regions between adjacent semiconductor channel layers.

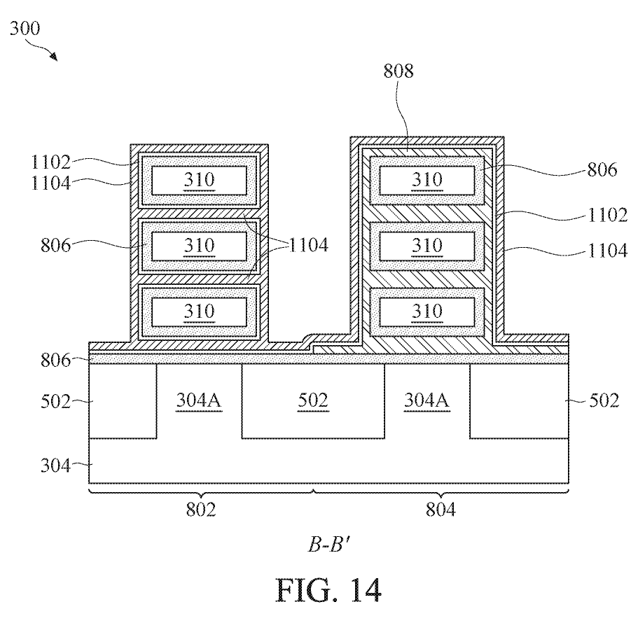

After depositing the second PWFM layer 1102, the method proceeds to block 228 where an N-type work function metal (NWFM) layer is formed. With reference to the example of FIGS. 13 and 14, in an embodiment of block 228, an NWFM layer 1104 is formed over the second PWFM layer 1102. As shown, the NWFM layer 1104 may be formed over the second PWFM layer 1102 in each of the N-type device region 802 and the P-type device region 804. In particular, the NWFM layer 1104 is deposited within the space 1106 between adjacent epitaxial layers 310 (adjacent semiconductor channel layers) and between the bottommost epitaxial layer 310 (bottommost semiconductor channel layer) and the substrate portion 304A (or mesa 304A). It is noted that the NWFM layer 1104 may fill the remaining space of the space 1106, such that the region between adjacent epitaxial layers 310 (or between adjacent semiconductor channel layers) is completely filled. Stated another way, the NWFM layer 1104 formed over a particular epitaxial layer 310 (semiconductor channel layer) merges with the NWFM layer 1104 formed on an adjacent epitaxial layer 310 (adjacent semiconductor channel layer). Further, as a result of depositing the NWFM layer 1104 in the space 1106, the NWFM layer 1104 (like the second PWFM layer 1102) may also surround (or wrap around) each of the epitaxial layers 310 (semiconductor channel layers) in the N-type device region 802. Also, in some embodiments, the NWFM layer 1104 deposited within the space 1106 may have a first thickness that is less than a second thickness of the NWFM layer 1104 deposited outside the space 1106.

In some embodiments, the NWFM layer 1104 may be deposited in-situ, after deposition of the second PWFM layer 1102, using an ALD process. Stated another way, and in some embodiments, the second PWFM layer 1102 and the NWFM layer 1104 may be deposited in sequence while maintaining the device 300 under vacuum conditions. More generally, the NWFM layer 1104 may be deposited using ALD, CVD, or other appropriate process. In some cases, the NWFM layer 1104 includes a nitrogen-containing layer (or Ti-based layer) such as a TiN layer. In some embodiments, the nitrogen-containing layer (or Ti-based layer) may include a multi-layer structure having an oxygen-containing layer disposed between first and second TiN layers. The oxygen-containing layer may include TiON, in some cases. In some alternative embodiments, the NWFM layer 1104 may include a titanium and aluminum-containing layer such as a TiAlC layer, which may also be referred to simply as an aluminum-containing layer. While some examples of materials that may be used to form the NWFM layer 1104 have been given, it will be understood that the above examples are merely exemplary, and other materials may be used without departing from the scope of the present disclosure. For example, in some cases, the NWFM layer 1104 may include TiAl, TaAl, TaAlC, Al-doped Ti, Al-doped TiN, Al-doped Ta, Al-doped TaN, HfAl, NbAlC, ZrAlC, a Ti-Al alloy, a Ta-Al alloy, a Hf-Al alloy, a TiC-Al alloy, a TiSi-Al alloy, an Nb-Al alloy, a Zr-Al alloy, or a combination thereof. In other examples, the NWFM layer 1104 may more generally include an aluminum-based metal alloy.

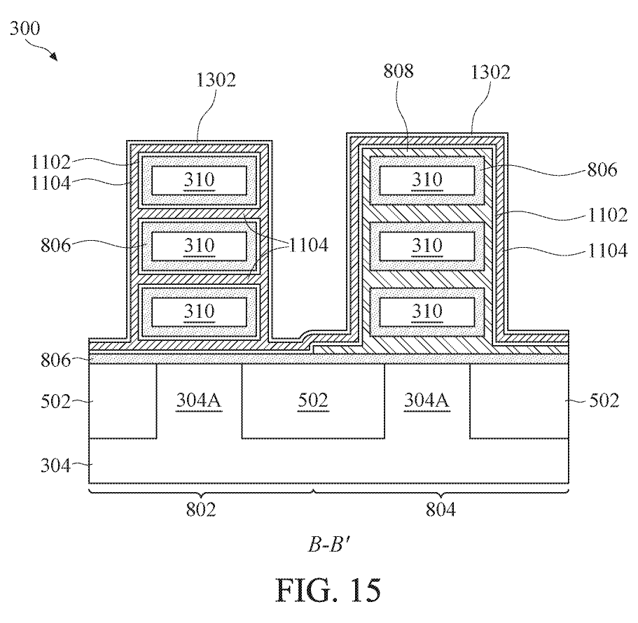

After forming the NWFM layer 1104, the method 200 proceeds to block 230 where a cap layer is formed. With reference to the example of FIGS. 14 and 15, in an embodiment of block 230, a cap layer 1302 is formed over the NWFM layer 1104 in each of the N-type device region 802 and the P-type device region 804. In some embodiments, the cap layer 1302 includes a silicon (Si) cap layer. The cap layer 1302, in various examples, may have a thickness in a range between about 5 – 15 Angstroms (or 0.5 – 1.5 nm). In some embodiments, the cap layer 1302 serves as a protection layer to prevent the NWFM layer 1104 from becoming oxidized during subsequent processing. In various embodiments, the cap layer 1302 may be deposited using ALD, CVD, or other appropriate process.

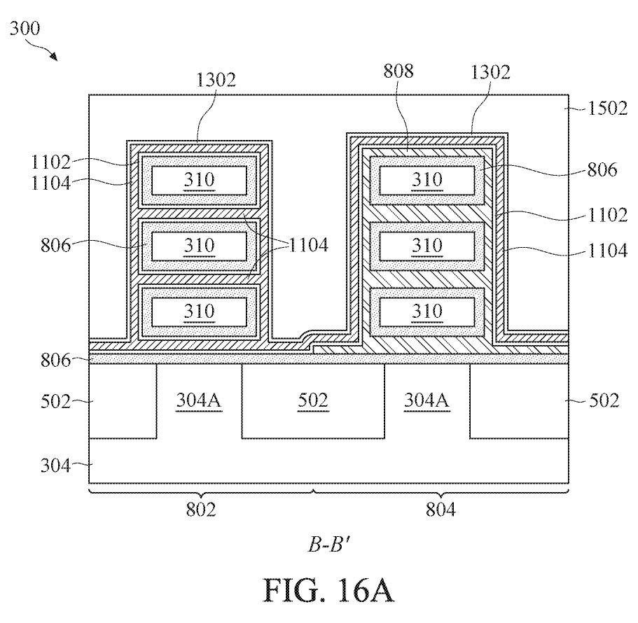

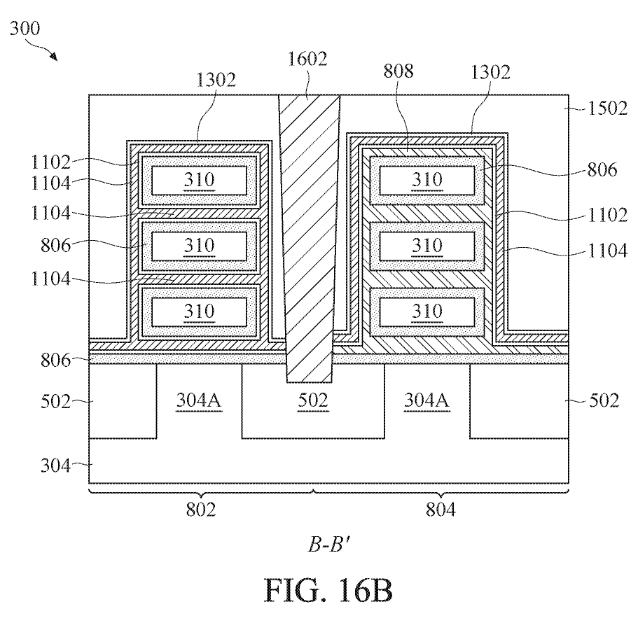

After forming the cap layer 1302, the method 200 proceeds to block 232 where a filling layer is formed. With reference to the example of FIG. 15 and FIG. 16A, in an embodiment of block 232, a filling layer 1502 is formed is formed over the cap layer 1302 in each of the N-type device region 802 and the P-type device region 804. In some embodiments, the filling layer 1502 includes a metal layer such as W and/or Mo. More generally, in various embodiments, the filling layer 1502 may include a metal, metal alloy, or metal silicide. Further, in some cases, the filling layer 1502 may include a single layer or alternatively a multi-layer structure. In addition, and in some embodiments, the filling layer 1502 may include Ti, Ag, Al, TiAlN, TaC, TaCN, TaSiN, Mn, Zr, TiN, TaN, Ru, Al, WN, Cu, Re, Ir, Co, Ni, other suitable metal materials or a combination thereof. In various embodiments, the filling layer 1502 may be formed by ALD, PVD, CVD, e-beam evaporation, or other suitable process. In some embodiments, the filling layer 1502 may be formed simultaneously in each of the N-type device region 802 and the P-type device region 804. However, in other embodiments, the filling layer 1502 may be formed separately in each of the N-type device region 802 and the P-type device region 804, which may use different metal layers. It is noted that in some cases, and as described in more detail below, the filling layer 1502 may not be formed within a gate trench (e.g., such as the trench 702) of a short-channel device, due to the small dimension of a gate trench above the epitaxial layers 310. After formation of the filling layer 1502, and in some embodiments, a CMP process may be performed to remove excess material and planarize a top surface of the device 300. In various embodiments, the filling layer 1502 may serve as a transistor gate electrode, and in at least some embodiments, the filling layer 1502 may include a polysilicon layer. In addition, and with respect to the devices shown and discussed, the gate dielectric layer 806, the second PWFM layer 1102, the NWFM layer 1104, and the filling layer 1502 may define a gate structure for an N-type device in the N-type device region 802, where at least some portions of the gate structure interpose each of the epitaxial layers 310 (semiconductor channel layers). Similarly, the gate dielectric layer 806, the first PWFM layer 808, the second PWFM layer 1102, the NWFM layer 1104, and the filling layer 1502 may define a gate structure for a P-type device in the P-type device region 804, where at least some portions of the gate structure interpose each of the epitaxial layers 310 (semiconductor channel layers). Moreover, and in view of the various exemplary material compositions previously discussed, the gate structure for the N-type device in the N-type device region 802 and/or the gate structure for the P-type device in the P-type device region 804 may include at least one dielectric layer and a Ti-based material.

With reference to the example of FIG. 16B, and in some embodiments, a cut metal gate (CMG) process may be performed after deposition of the filling layer 1502, for example, to separate (or electrically isolate) an N-type device in the N-type device region 802 from a P-type device in the P-type device region 804. By way of example, the CMG process may include forming a cut metal gate trench by removing portions of the filling layer 1502, the cap layer 1302, the NWFM layer 1104, the second PWFM layer 1102, and the first PWFM 808 disposed along a boundary between the N-type device region 802 and the P-type device region 804. Thereafter, the cut metal gate trench is refilled with one or more dielectric layers to completely fill the cut metal gate trench and form a CMG isolation structure 1602. In some embodiments, the one or more dielectric layers used to form the CMG isolation structure 1602 may include a nitride layer such as SiN, SiO₂, silicon oxynitride, FSG, a low-K dielectric, combinations thereof, and/or other suitable materials known in the art. In various examples, the one or more dielectric layers used to form the CMG isolation structure 1602 may be deposited by a CVD process, an SACVD process, a flowable CVD process, an ALD process, a PVD process, and/or other suitable process. In various cases, a CMP may be performed after deposition of the one or more dielectric layers to remove excess material and planarize a top surface of the device 300. In some embodiments, and as shown in FIG. 16B, the cut metal gate trench (and the CMG isolation structure 1602 formed therein) may extend at least partially into an underlying isolation region 502. Further, in some embodiments, the cut metal gate trench (and the CMG isolation structure 1602 formed therein) may have tapered sidewalls such that a first width at a top of the CMG isolation structure 1602 is greater than a second width at a bottom of the CMG isolation structure 1602. As also shown in the example of FIG. 16B, a first sidewall of the CMG isolation structure 1602 may interface with a first portion of the filling layer 1502 formed in the N-type device region 802, and a second sidewall of the CMG isolation structure 1602 may interface with a second portion of the filling layer 1502 formed in the P-type device region 804. Further, in some embodiments and since different metal layers may be used as the filling layer 1502 in each of the N-type device region 802 and the P-type device region 804, the first sidewall of the CMG isolation structure 1602 may interface with a first metal layer formed in the N-type device region 802 and the second sidewall of the CMG isolation structure 1602 may interface with a second metal layer, different than the first metal layer, formed in the P-type device region 804. In addition, and in some embodiments, the first sidewall of the CMG isolation structure 1602 may interface with at least portions of the cap layer 1302, the NWFM layer 1104, and the second PWFM layer 1102 formed in the N-type device region 802, and the second sidewall of the CMG isolation structure 1602 may interface with at least portions of the cap layer 1302, the NWFM layer 1104, the second PWFM layer 1102, and the first PWFM 808 formed in the P-type device region 804, as shown in FIG. 16B.

FIGS. 17A and 17B provide cross-sectional views of a device structure, formed in accordance with the method described herein, in each of the N-type device region 802 and the P-type device region 804, along a plane substantially parallel to a plane defined by section A-A’ of FIG. 1 (e.g., along the direction of a fin). As shown, an N-type device 300A in the N-type device region 802 and a P-type device 300B in the P-type device region 804 each include many of the same features as discussed above, such as the substrate portion 304A (or mesa 304A) and the stack of epitaxial layers 310 (stack of semiconductor channel layers) disposed over the substrate portion 304A, among others. Further, each of the N-type device 300A and the P-type device 300B have a portion of a respective gate structure interposing adjacent epitaxial layers 310. In particular, between adjacent epitaxial layers 310 and between the bottommost epitaxial layer 310 and the substrate portion 304A, the N-type device 300A includes a first portion of a gate structure that includes a portion of the NWFM layer 1104, a portion of the second PWFM layer 1102 surrounding the portion of the NWFM layer 1104, and the gate dielectric layer 806 surrounding the portion of the second PWFM layer 1102. As shown, the inner spacers 610 are also disposed on opposite lateral ends of the first portion of the gate structure and beneath the gate spacers 608. In some embodiments, a second portion of the gate structure of the N-type device 300A, disposed over a topmost epitaxial layer 310 and between gate spacers 608, includes the gate dielectric layer 806 formed over a top surface of the topmost epitaxial layer 310 and along sidewalls of the gate spacers 608, the second PWFM layer 1102 formed over the gate dielectric layer 806, the NWFM layer 1104 formed over the second PWFM layer 1102, and the filling layer 1502 formed over the NWFM layer 1104.

In contrast, between adjacent epitaxial layers 310 and between the bottommost epitaxial layer 310 and the substrate portion 304A, the P-type device 300B includes a first portion of a gate structure that includes a portion of the first PWFM layer 808 and the gate dielectric layer 806 surrounding the portion of the first PWFM layer 808. As shown, the inner spacers 610 are also disposed on opposite lateral ends of the first portion of the gate structure and beneath the gate spacers 608. In some embodiments, a second portion of the gate structure of the P-type device 300B, disposed over a topmost epitaxial layer 310 and between gate spacers 608, includes the gate dielectric layer 806 formed over a top surface of the topmost epitaxial layer 310 and along sidewalls of the gate spacers 608, the first PWFM layer 808 formed over the gate dielectric layer 806, the second PWFM layer 1102 formed over the first PWFM layer 808, the NWFM layer 1104 formed over the second PWFM layer 1102, and the filling layer 1502 formed over the NWFM layer 1104.

As previously noted, the filling layer 1502 may not be formed within the gate trench (e.g., such as the trench 702) of short-channel devices. Thus, and still with reference to FIGS. 17A and 17B, the illustrated N-type device 300A in the N-type device region 802 and the P-type device 300B in the P-type device region 804 may, in some examples, include long-channel devices. In the case of short-channel devices, and in some embodiments, the small dimension of the gate trench (e.g., such as the gate trench 702) above the epitaxial layers 310 and between the gate spacers 608 may cause portions of the NWFM layer 1104 formed within the gate trench to merge and completely fill the gate trench within the second portion of the gate structure (above the topmost epitaxial layer 310 and between the gate spacers 608). As a result, there will be no remaining space in the gate trench within which the filling layer 1502 may be formed. In various cases, such merging of the portions of the NWFM layer 1104 within the gate trench may occur for one or both of the N-type device 300A and the P-type device 300B. In some embodiments, and due to the presence of the first PWFM layer 808 in the P-type device 300B, the P-type device 300B may be more susceptible to merging of the portions of the NWFM layer 1104 within the gate trench. Thus, in some cases and for short-channel devices, the P-type device 300B may include the merged NWFM layer 1104 in the gate trench within the second portion of the gate structure, but may not include the filling layer 1502, while the N-type device 300A still includes the filling layer 1502 formed over the NWFM layer 1104 in the gate trench within the second portion of the gate structure.

Generally, the semiconductor device 300 may undergo further processing to form various features and regions known in the art. For example, further processing may form various contacts/vias/lines and multilayer interconnect features (e.g., metal layers and interlayer dielectrics) on the substrate 304, configured to connect the various features to form a functional circuit that may include one or more multi-gate devices (e.g., one or more GAA transistors). In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 200, and some process steps described above may be modified, replaced, or eliminated in accordance with various embodiments of the method 200.

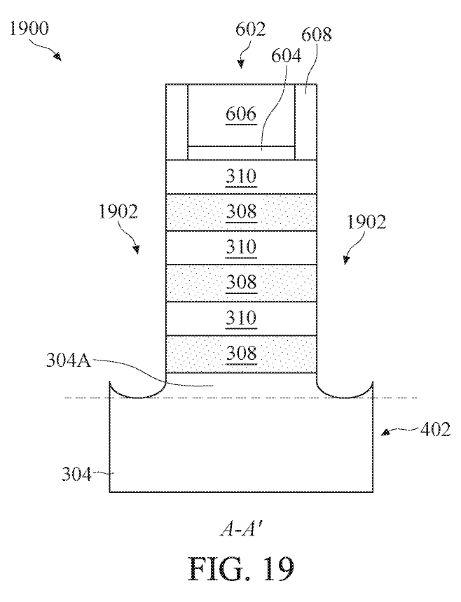

Referring now to FIG. 18, illustrated therein is a method 1800 of semiconductor fabrication including fabrication of a semiconductor device 1900 (e.g., which includes a multi-gate device), in accordance with various embodiments. The method 1800 is similar to the method 200, described above. Thus, for clarity of discussion, attention will largely be given to those features and/or steps which differ from those of the method 200. In particular, the method 1800 includes a process in which a dielectric interposer layer replaces the epitaxial layers 308 (the dummy layers) of the stack 312 of epitaxial layers 308, 310, prior to performing high-temperature thermal processes, in order to prevent Ge diffusion into neighboring semiconductor channel layers (the epitaxial layers 310), which could result in an undesirable SiGe/Si intermix layer. The method 1800 is discussed below with reference to FIGS. 19-24, 25A, and 25B, which each provide cross-sectional views of an embodiment of the semiconductor device 1900 along a plane substantially parallel to a plane defined by section A-A’ of FIG. 1 (e.g., along the direction of a fin). The method 1800 may at times also be discussed with reference to the figures associated with the method 200. In some embodiments, the method 1800 may be used to fabricate the multi-gate device 100, described above with reference to FIG. 1. Thus, one or more aspects discussed above with reference to the multi-gate device 100 may also apply to the method 1800. It is understood that the method 1800 includes steps having features of a CMOS technology process flow and thus, are only described briefly herein. Also, additional steps may be performed before, after, and/or during the method 1800.

The method 1800 begins at block 1802, which is substantially the same as blocks 202-208 of the method 200, described above. Referring to the example of FIG. 19, in an embodiment of block 1802, the stack 312 of epitaxial layers 308, 310 have been formed over the substrate 304, the stack of epitaxial layers 308, 310 have been patterned to form fins 402 extending from the substrate 304, isolation regions 502 have been formed on either side of the fins (e.g., such as the fin 402) to isolate neighboring fins from each other, and dummy gates 602 and gate spacers 608 have been formed.

The method 1800 proceeds to block 1804 where a source/drain etch process is performed. In the method 200, the source/drain etch process was described as being part of block 210, where the inner spacers and source/drain features are formed. At block 1804 of the method 1800, the source/drain etch process removes portions of epitaxial layers 308, 310 in source/drain regions of the device 1900 (e.g., adjacent to and on either side of the dummy gate 602) to form trenches 1902 which expose underlying portions of the substrate 304. The source/drain etch process also serves to expose lateral surfaces of the epitaxial layers 308, 310, as shown in FIG. 19. By way of example, the source/drain etch process may include a dry etching process, a wet etching process, and/or a combination thereof.

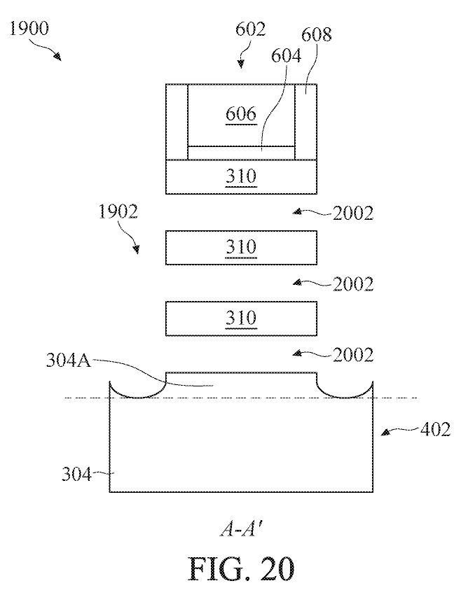

The method 1800 proceeds to block 1806 where dummy epitaxial layers are removed. Referring to the example of FIGS. 19 and 20, in an embodiment of block 1806, the dummy epitaxial layers (the epitaxial layers 308) are selectively removed (e.g., using a selective etching process), while the semiconductor channel layers (the epitaxial layers 310) remain substantially unetched. In various examples, the selective removal of the dummy epitaxial layers (the epitaxial layers 308) completely removes the epitaxial layers 308, thereby eliminating the possibility of Ge diffusion, formation of a SiGe/Si intermix layer, and/or Ge residue remaining after subsequent device processing. The selective etching process to remove the epitaxial layers 308 may be performed through the trenches 1902 provided by the source/drain etch process (block 1804). In some embodiments, the selective etching process may include a selective wet etching process. In some cases, the selective wet etching includes ammonia (NH₃) and/or ozone (O₃). As merely one example, the selective wet etching process includes tetra-methyl ammonium hydroxide (TMAH). In some embodiments, the selective etching process may include a dry, plasma-free etching process. In some examples, the selective etching process may include etching using a standard clean 1 (SC-1) solution, a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch. It is noted that as a result of the selective removal of the dummy epitaxial layers (the epitaxial layers 308), gaps (or cavities) 2002 are formed between the adjacent semiconductor channel layers (the epitaxial layers 310).

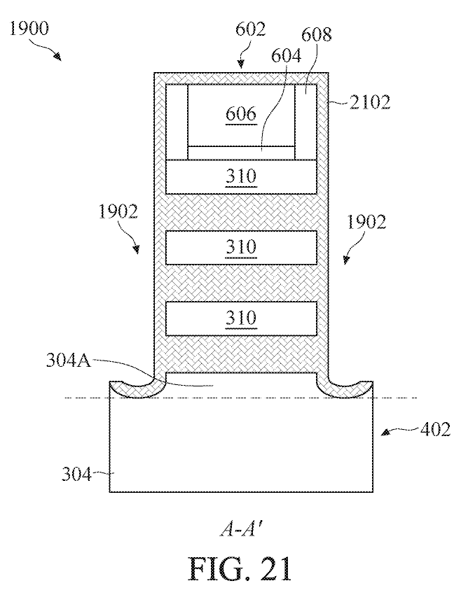

After removal of the dummy epitaxial layers (the epitaxial layers 308), the method 1800 then proceeds to block 1808 where a dielectric interposer layer is deposited. Referring to FIGS. 20 and 21, in an embodiment of block 1808, a dielectric interposer layer 2102 is conformally deposited over the device 1900. In particular, the dielectric interposer layer 2102 is conformally deposited within the trenches 1902 and within the gaps (or cavities) 2002 that were previously formed between the adjacent semiconductor channel layers (the epitaxial layers 310). In some embodiments, the dielectric interposer layer 2102 may be deposited such that it completely fills the gaps (or cavities) 2002.

In some embodiments, the dielectric interposer layer 2102 may include an oxygen-containing layer (e.g., including an oxide layer such as SiO₂), a nitrogen-containing layer (e.g., including a nitride layer such as SiN), an oxygen-and-nitrogen-containing layer such as silicon oxynitride (SiON), a metal oxide such as aluminum oxide (Al₂O₃), a carbon-containing layer such as silicon carbide (SiC), silicon carbon nitride (SiCN), silicon oxycarbide (SiOC), or silicon oxycarbonitride (SiOCN), a low-K material (e.g., with a dielectric constant ‘k’ < 7), and/or combinations thereof. In some cases, the dielectric interposer layer 2102 may be conformally deposited using processes such as a an ALD process, a CVD process, or other suitable process. In accordance with embodiments of the present disclosure, the dielectric interposer layer 2102 may serve as a disposable interposer, as discussed further herein. Thus, in some cases, the dielectric interposer layer 2102 may also be referred to a sacrificial layer.

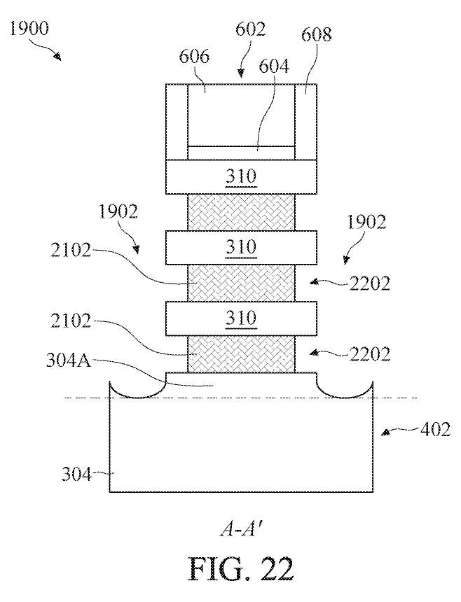

The method 1800 then proceeds to block 1810 where the dielectric interposer layer previously deposited is recessed. Referring to FIGS. 21 and 22, in an embodiment of block 1810, a recessing process is performed to the device 1900. In particular, and in various examples, the recessing process etches the dielectric interposer layer 2102 from over a top surface of the device 1900. Further, the recessing process etches the dielectric interposer layer 2102 from along sidewalls of the trenches 1902 and at least partially etches the dielectric interposer layer 2102 from between lateral ends of the adjacent semiconductor channel layers (the epitaxial layers 310) to form recesses 2202, while the dielectric interposer layer 2102 remains at least partially disposed between the adjacent semiconductor channel layers (the epitaxial layers 310). The portions of the dielectric interposer layer 2102 that remain between the adjacent semiconductor channel layers will serve as disposable interposers, having effectively replaced the SiGe interposers (epitaxial layers 308) previously disposed between the semiconductor channel layers (epitaxial layers 310). During a later stage of processing, the disposable interposers will be removed and replaced by a portion of a gate structure that interfaces respective adjacent inner spacers. In some examples, such as when the dielectric interposer layer 2102 includes an oxide layer, the recessing process (block 1810) includes a vapor dilute hydrofluoric (dHF) acid etch. In some embodiments, the recessing process (block 1810) may be performed using a wet etch process such as a phosphoric acid (H₃PO₄) chemical etch of the dielectric interposer layer 2102. In some alternative examples, cycles of a high temperature sulfuric peroxide mixture (HTSPM) and dilute hydrofluoric acid (dHF), ozone (O₃) and dHF, or a combination thereof, may be used to perform the recessing process.

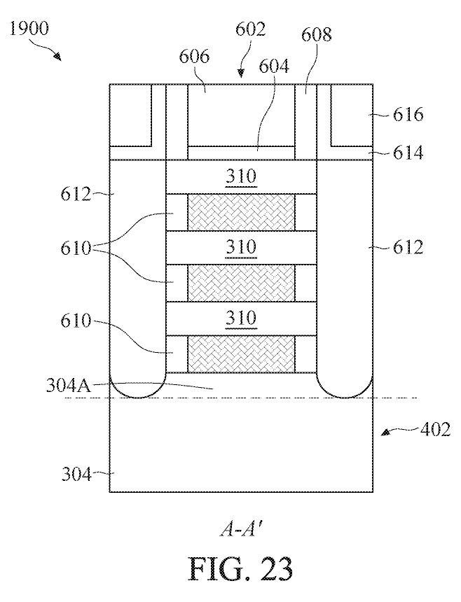

The method 1800 proceeds to block 1812, which is substantially the same as blocks 210-232 of the method 200, described above. One distinction, however, is that the recessing process used to form the recesses 2202 (within which inner spacers will be formed) has been previously performed at block 1810. Other differences will be noted below, as needed. Referring to the example of FIGS. 22 and 23, in an embodiment of block 1812 and after the recesses 2202 have been formed, the inner spacers 610 are formed within the recesses 2202, in substantially the same manner as described above. It is also once again noted that the formation of the inner spacers 610, including respective manufacturing steps, may be optional. That is, the formation of the inner spacers 610 may be omitted, and the inner spacers 610 may not exist in the final structure of the device 1900, in some embodiments. In a further embodiment of block 1812, the source/drain features 612 are formed within the trenches 1902, after which the CESL 614 and ILD layer 616 are formed, as described above.

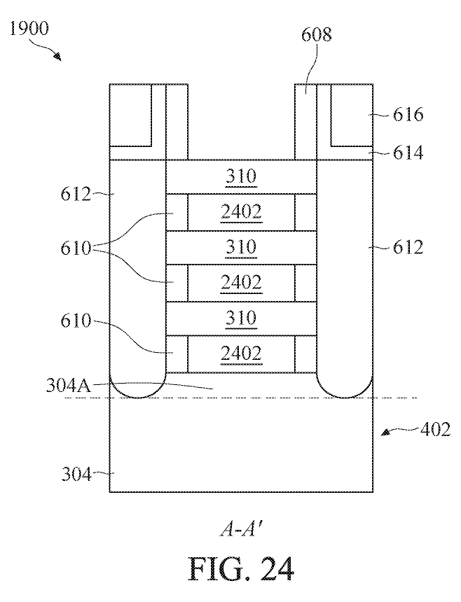

Thereafter, in a further embodiment of block 1812 and with reference to the example of FIGS. 23 and 24, the dummy gate 602 (including the electrode layer 606 and the dielectric layer 604) is removed, as previously discussed. It is noted that since the dielectric layer 604 and the portions of the dielectric interposer layer 2102 that remain disposed between adjacent semiconductor channel layers (the epitaxial layers 310) in the channel region may be composed of the same or similar materials (e.g., both the dielectric layer 604 and the dielectric interposer layer 2102 may include an oxide layer, a nitride layer, or other similar dielectric layer), the process performed to remove the dielectric layer 604 may additionally selectively remove the dielectric interposer layer 2102 at the same time (e.g., during the same etching process) while the semiconductor channel layers (the epitaxial layers 310) and the inner spacers 610 remain substantially unetched. It is further noted that removal of the electrode layer 606 and the dielectric layer 604 provides for removal of the dummy gate 602, for example, as part of a replacement gate process. Thus, as merely one example, if both the dielectric layer 604 and the dielectric interposer layer 2102 include an oxide layer (or nitride layer, or other similar dielectric layer), the disposable interposers will be removed together with the dielectric layer 604 as part of the replacement gate process.

As a result of the selective removal of the remaining portions of the dielectric interposer layer 2102 (the disposable interposers), gaps 2402 are formed between the adjacent semiconductor channel layers (the epitaxial layers 310). By way of example, the gaps 2402 serve to expose first portions of the epitaxial layers 310 between opposing inner spacers 610, while second portions of the epitaxial layers 310 remain covered by the inner spacers 610. Like the method 200, portions of gate structures (e.g., including a metal gate stack having an interfacial layer, a high-K dielectric layer, and one or more metal electrode layers) will be formed within the gaps 2402 between adjacent semiconductor channel layers (the epitaxial layers 310) and in contact with (or interfacing) the inner spacers 610.

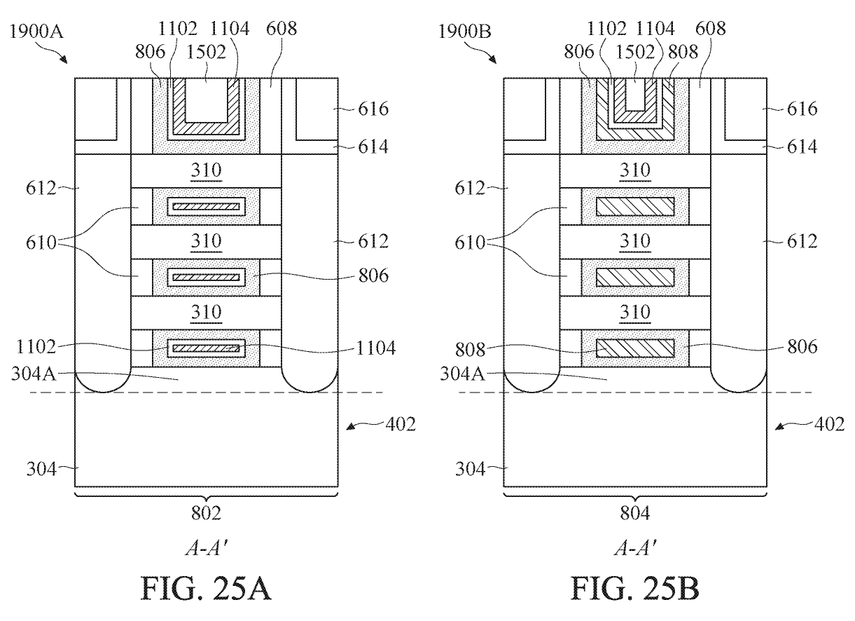

At this stage of processing of the method 1800, the device 1900 is substantially the same as the device 300 shown in FIG. 7 (processed according to the method 200). Thus, in some embodiments, the remaining processing of the device 1900 according to the method 1800 may proceed in substantially the same manner as has been described with reference to the method 200. It is also noted that while the steps of the method 1900 discussed thus far may be largely applicable to both N-type and P-type GAA devices, in some embodiments, the disclosed dielectric interposer layer may be used in the fabrication of only N-type GAA devices, only P-type GAA devices, or both N-type and P-type GAA devices. It is also once again noted that the source/drain features 612 may be formed separately for N-type and P-type devices. In various embodiments, the remaining steps of block 1812 (including blocks 214-232) may be more specifically differentiated between processes performed in each of N-type and P-type device regions of the substrate 304, in the same manner as discussed above with reference to the method 200. In addition, since the remaining steps of block 1812 (including blocks 214-232) may be substantially the same as discussed above with reference to the method 200, and for the sake of clarity, such discussion is not repeated here. FIGS. 25A and 25B illustrate alternative views of a final device structure, in accordance with the method 1800, for an N-type device 1900A formed in the N-type device region 802 and for a P-type device 1900B formed in the P-type device region 804, respectively. The examples of FIGS. 25A and 25B may be substantially the same as the examples of FIGS. 17A and 17B, discussed above, however bottom surfaces of the source/drain features 612 in the examples of FIGS. 25A and 25B may have more curvature due at least in part to the processing associated with the dielectric interposer layer. Moreover, the devices 1900A and 1900B will also be substantially free of a SiGe/Si intermix layer and/or Ge residue (e.g., along top and bottom surfaces of the epitaxial layers 310), thereby enhancing device performance.

With respect to the description provided herein, disclosed are methods and structures for skipping a PCA process for highly-scaled GAA devices, thereby preventing defects and reducing costs while maintaining or improving device performance and reliability. More generally, embodiments of the present disclosure include: (i) skipping the PCA process, (ii) addition of a nitridation anneal, (iii) addition of a thin P-type work function metal (PWFM) layer right before deposition of an N-type work function metal (NWFM) layer, and (iv) fine tuning middle-end-of-line (MEOL) thermal processing. In some embodiments, skipping the PCA process reduces cost, even with the addition of other processing stages disclosed herein (e.g., such as the nitridation anneal and addition of thin PWFM layer). In some embodiments, the nitridation anneal serves to maintain the same thermal budget as the anneal of the PCA process used in other implementations, and incorporates a percentage of nitrogen, N% into the gate dielectric layer to control capacitance equivalent thickness (CET) and improve RO speed. In some embodiments, the addition of a thin PWFM layer, right before the NWFM layer deposition, provides for intermixing with the gate oxide, thereby preventing aluminum (Al) diffusion from NWFM layer and improving TDDB, a task previously accomplished by TiN capping and annealing (e.g., as part of the PCA process). In various embodiments, the disclosed methods may be applied to N-type GAA devices, P-type GAA devices, or both N-type and P-type GAA devices. By employing the methods disclosed herein, defects are reduced, device performance and reliability are increased, and RO speed is increased.

Thus, one of the embodiments of the present disclosure described a method that includes providing a first plurality of stacked channel layers in a first substrate region and a second plurality of stacked channel layers in a second substrate region, the first plurality of stacked channel layers and the second plurality of stacked channel layers extending in a first direction in a top-down view. In some embodiments, the method further includes forming a gate dielectric layer wrapping around at least one channel layer of respective ones of the first plurality of stacked channel layers and the second plurality of stacked channel layers, in a cross-sectional view. In some embodiments, a dielectric constant of the gate dielectric layer is greater than a dielectric constant of a sidewall spacer formed on a sidewall of a gate structure in the first and second substrate regions, the gate structure and the sidewall spacer extending in a second direction in the top-down view, the second direction different than the first direction. In some embodiments, the method further includes introducing nitrogen into the gate dielectric layer. In some embodiments, the method further includes after introducing the nitrogen into the gate dielectric layer, forming a first work function metal (WFM) layer over the gate dielectric layer in the second substrate region, the first WFM layer wrapping around the at least one channel layer of the second plurality of stacked channel layers. In some embodiments, the method further includes forming a second WFM layer, the second WFM layer wrapping around the at least one channel layer of the first plurality of stacked channel layers.

In another of the embodiments, discussed is a method that includes forming a first gate dielectric layer surrounding one or more first epitaxial layers in a first device type region and a second gate dielectric layer surrounding one or more second epitaxial layers in a second device type region. In some embodiments, the method further includes performing a first anneal process in a nitrogen-containing gas ambient. In some embodiments, the method further includes after performing the first anneal process, forming a first one of a first type work function metal layer over the second gate dielectric layer in the second device type region. In some embodiments, the method further includes forming a second type work function metal layer, the second type work function metal layer wrapping around at least one of the one or more first epitaxial layers in the first device type region. In some embodiments, the first gate dielectric layer and the second type work function metal layer define at least part of a gate structure for a first device in the first device type region, the gate structure including at least one dielectric layer and a Ti-based material. In some embodiments, a dielectric constant of the first gate dielectric layer is greater than a dielectric constant of a sidewall spacer formed on a sidewall of the gate structure.

In yet another of the embodiments, discussed is a semiconductor device including a plurality of semiconductor channel layers disposed over a substrate. In some embodiments, the semiconductor device further includes a gate dielectric layer surrounding at least one of the plurality of semiconductor channel layers, where the gate dielectric layer includes nitrogen. In some embodiments, the semiconductor device further includes an aluminum-blocking layer formed over the gate dielectric layer and surrounding the at least one of the plurality of semiconductor channel layers, the aluminum-blocking layer and the gate dielectric layer at least partially intermixed to form an intermix layer at a boundary between the gate dielectric layer and the aluminum-blocking layer. In some embodiments, the semiconductor device further includes a Ti-based layer formed over the aluminum-blocking layer and surrounding the at least one of the plurality of semiconductor channel layers. In some embodiments, the semiconductor device further includes a source/drain feature interfacing lateral ends of the plurality of semiconductor channel layers, where a contact etch stop layer (CESL) is disposed over the source/drain feature and an inter-layer dielectric (ILD) layer is disposed over the CESL, and where the CESL and the ILD layer are composed of different materials. In some embodiments, the gate dielectric layer, the aluminum-blocking layer, and the Ti-based layer collectively fill a space between adjacent semiconductor channel layers of the plurality of semiconductor channel layers. In some embodiments, a first dielectric constant of the gate dielectric layer is at least two times greater than a second dielectric constant of the ILD layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a first plurality of stacked channel layers in a first substrate region and a second plurality of stacked channel layers in a second substrate region, the first plurality of stacked channel layers and the second plurality of stacked channel layers extending in a first direction in a top-down view;
forming a gate dielectric layer wrapping around at least one channel layer of respective ones of the first plurality of stacked channel layers and the second plurality of stacked channel layers, in a cross-sectional view, wherein a dielectric constant of the gate dielectric layer is greater than a dielectric constant of a sidewall spacer formed on a sidewall of a gate structure in the first and second substrate regions, the gate structure and the sidewall spacer extending in a second direction in the top-down view, the second direction different than the first direction;
introducing nitrogen into the gate dielectric layer;
after introducing the nitrogen into the gate dielectric layer, forming a first work function metal (WFM) layer over the gate dielectric layer in the second substrate region, the first WFM layer wrapping around the at least one channel layer of the second plurality of stacked channel layers; and
forming a second WFM layer, the second WFM layer wrapping around the at least one channel layer of the first plurality of stacked channel layers.

2. The method of claim 1, further comprising:
prior to forming the second WFM layer, forming a third WFM layer over the gate dielectric layer in the first substrate region and over the first WFM layer in the second substrate region, the third WFM layer wrapping around the at least one channel layer of the first plurality of stacked channel layers;
wherein forming the second WFM layer further includes forming the second WFM layer over the third WFM layer in the first and second substrate regions.

3. The method of claim 2, wherein the first WFM layer includes a first P-type work function metal (PWFM) layer, wherein the second WFM layer includes an N-type work function metal (NWFM) layer, and wherein the third WFM layer includes a second P-type work function metal (PWFM) layer.

4. The method of claim 2, wherein in the first substrate region, the gate dielectric layer, the third WFM layer, and the second WFM layer collectively fill a first space between adjacent channel layers of the first plurality of stacked channel layers, and wherein in the second substrate region, the gate dielectric layer and the first WFM layer collectively fill a second space between adjacent channel layers of the second plurality of stacked channel layers.

5. The method of claim 1, wherein the first substrate region includes an N-type device region, and wherein the second substrate region includes a P-type device region.

6. The method of claim 1, wherein the introducing the nitrogen into the gate dielectric layer includes performing a nitridation anneal at a temperature in a range between about 800C-1250C.

7. The method of claim 1, wherein the gate dielectric layer includes an interfacial layer (IL) and a high-K dielectric layer over the IL, and wherein the introducing nitrogen into the gate dielectric layer causes the nitrogen to be incorporated into both the high-K dielectric layer and the IL.

8. The method of claim 2, wherein the third WFM layer is thinner than the first WFM layer.

9. The method of claim 2, wherein the first WFM layer and the third WFM layer are made of different materials.

10. The method of claim 2, wherein the first WFM layer and the third WFM layer are made of a same material.

11. A method, comprising:
forming a first gate dielectric layer surrounding one or more first epitaxial layers in a first device type region and a second gate dielectric layer surrounding one or more second epitaxial layers in a second device type region;
performing a first anneal process in a nitrogen-containing gas ambient;
after performing the first anneal process, forming a first one of a first type work function metal layer over the second gate dielectric layer in the second device type region; and
forming a second type work function metal layer, the second type work function metal layer wrapping around at least one of the one or more first epitaxial layers in the first device type region;
wherein the first gate dielectric layer and the second type work function metal layer define at least part of a gate structure for a first device in the first device type region, the gate structure including at least one dielectric layer and a Ti-based material; and
wherein a dielectric constant of the first gate dielectric layer is greater than a dielectric constant of a sidewall spacer formed on a sidewall of the gate structure.

12. The method of claim 11, further comprising:
prior to forming the second type work function metal layer, forming a second one of the first type work function metal layer over the first gate dielectric layer in the first device type region and over the first one of a first type work function metal layer in the second device type region;
wherein forming the second type work function metal layer includes forming the second type work function metal layer over the second one of the first type work function metal layer.

13. The method of claim 11, wherein after the first anneal process, nitrogen is incorporated into an interfacial layer (IL) and a high-K dielectric layer of the first and second gate dielectric layers.

14. The method of claim 12, wherein a thickness of the second one of the first type work function metal layer is less than a thickness of the first one of the first type work function metal layer.

15. The method of claim 12, wherein the second one of the first type work function metal layer and the first one of the first type work function metal layer are made of different materials.

16. The method of claim 12, wherein the second one of the first type work function metal layer and the first one of the first type work function metal layer are made of a same material.

17. The method of claim 11, further comprising:
prior to performing the first anneal process, performing a dipole modification process in at least one of the first and second device type regions, wherein the dipole modification process comprises:
depositing a dipole inducing layer over at least one of the first gate dielectric layer and the second gate dielectric layer; and
performing a second anneal process to drive atoms from the dipole inducing layer into the at least one of the first gate dielectric layer and the second gate dielectric layer.

18. A semiconductor device, comprising:
a plurality of semiconductor channel layers disposed over a substrate;
a gate dielectric layer surrounding at least one of the plurality of semiconductor channel layers, wherein the gate dielectric layer includes nitrogen;
an aluminum-blocking layer formed over the gate dielectric layer and surrounding the at least one of the plurality of semiconductor channel layers, the aluminum-blocking layer and the gate dielectric layer at least partially intermixed to form an intermix layer at a boundary between the gate dielectric layer and the aluminum-blocking layer;
a Ti-based layer formed over the aluminum-blocking layer and surrounding the at least one of the plurality of semiconductor channel layers; and
a source/drain feature interfacing lateral ends of the plurality of semiconductor channel layers, wherein a contact etch stop layer (CESL) is disposed over the source/drain feature and an inter-layer dielectric (ILD) layer is disposed over the CESL, and wherein the CESL and the ILD layer are composed of different materials;
wherein the gate dielectric layer, the aluminum-blocking layer, and the Ti-based layer collectively fill a space between adjacent semiconductor channel layers of the plurality of semiconductor channel layers; and
wherein a first dielectric constant of the gate dielectric layer is at least two times greater than a second dielectric constant of the ILD layer.

19. The semiconductor device of claim 18, wherein the aluminum-blocking layer includes a P-type work function metal (PWFM) layer.

20. The semiconductor device of claim 18, wherein the gate dielectric layer includes an interfacial layer (IL) and a high-K dielectric layer over the IL, and wherein both the high-K dielectric layer and the IL include the nitrogen.
